(19) United States
(12) Patent Application Publication
(10) Pub. No.: US 2025/0253089 A1
(43) Pub. Date: Aug. 7, 2025

(54) INDUCTANCE STRUCTURE, AND FILTER

(71) Applicants: Beijing BOE Sensor Technology Co., Ltd., Beijing (CN); BOE Technology Group Co., Ltd., Beijing (CN); Beijing BOE Technology Development Co., Ltd., Beijing (CN)

(72) Inventors: Yulin Feng, Beijing (CN); Yue Li, Beijing (CN); Chunnan Feng, Beijing (CN); Xue Cao, Beijing (CN); Guohan Yang, Beijing (CN); Yuelei Xiao, Beijing (CN); Qichang An, Beijing (CN); Yifan Wu, Beijing (CN); Biqi Li, Beijing (CN)

(73) Assignees: Beijing BOE Sensor Technology Co., Ltd., Beijing (CN); BOE Technology Group Co., Ltd., Beijing (CN); Beijing BOE Technology Development Co., Ltd., Beijing (CN)

(21) Appl. No.: 18/695,092

(22) PCT Filed: Jul. 27, 2023
(86) PCT No.: PCT/CN2023/109646

§ 371 Date: Mar. 25, 2024

(51) Int. Cl. H01F 27/28

(52) U.S. Cl. CPC H01F 27/2804; H01F 2027/2809

(57) ABSTRACT

An inductance structure and a filter, and relates to the technical field of passive devices. The inductance structure includes a dielectric substrate, a first conductive structure and a second conductive structure; the dielectric substrate is provided with a plurality of connection through-holes penetrating in a thickness direction thereof; connection electrodes are provided in the connection through-holes; the first conductive structure and the second conductive structure are electrically connected by the connection electrodes to form a coil of the inductance structure; one of the first conductive structure and the second conductive structure includes at least three sub-layers, and the other includes at least one sub-layer; and orthographic projections of two of the sub-layers of the first conductive structure and the second conductive structure on the dielectric substrate at least partially overlap, and the flow directions of currents of both are roughly parallel.

### TECHNICAL FIELD

The present disclosure relates to the technical field of displaying and more particularly, to an inductance structure and a filter.

### BACKGROUND

With the rapid development of electronic communication technology, 5G technology is continuously popularized, the frequency range of signal transmission becomes wider and wider, which greatly improves the speed of signal transmission between devices and promotes the rapid development of social information transmission. Meanwhile, a variety of new process technology continues to emerge. With the rapid development of integration technology, more and more devices are integrated in the small size of chips. On the one hand, it greatly reduces the size of the electronic device. On the other hand, it enriches various media functions within the device. Device dimensions allow iteration from macroscopic centimeter dimensions to microscopic micrometer or even nanometer dimensions.

The 5G technology first expands the range of signal transmission, and a large increase in signal frequencies places higher demands on the electronics within the device. At present, it is necessary to provide an inductance structure having a small size and a high inductance value.

### SUMMARY

The technical solution adopted in embodiments of the present disclosure is as follows.

In a first aspect, embodiments of the present disclosure provide an inductance structure including:
a dielectric substrate, wherein the dielectric substrate is provided with a plurality of connection through-holes penetrating in a thickness direction of the dielectric substrate, connection electrodes are provided in the connection through-holes, and the dielectric substrate further includes a first surface and a second surface oppositely disposed in the thickness direction of the dielectric substrate;
a first conductive structure disposed on the first surface; and
a second conductive structure disposed on the second surface;
wherein the first conductive structure and the second conductive structure are electrically connected by the connection electrodes to form a coil of the inductance structure; one of the first conductive structure and the second conductive structure includes at least three sub-layers, and the other includes at least one sub-layer; and orthographic projections of two of the sub-layers of the first conductive structure and the second conductive structure on the dielectric substrate at least partially overlap, and flow directions of currents of the two of the sub-layers are roughly parallel.

In at least one embodiment provided by the present disclosure, the sub-layer in the first conductive structure is a first conductive sub-layer and the sub-layer in the second conductive structure is a second conductive sub-layer;
wherein the first conductive structure includes at least three first conductive sub-layers and the second conductive structure includes at least three second conductive sub-layers; or
the first conductive structure includes the at least three first conductive sub-layers and the second conductive structure includes one of the second conductive sub-layers.

In at least one embodiment provided by the present disclosure, the orthographic projections of at least two of the first conductive sub-layers on the dielectric substrate at least partially overlaps, and the flow directions of the currents of both are parallel.

In at least one embodiment provided by the present disclosure, the orthographie projection of at least one of the first conductive sub-layers on the dielectric substrate and the orthographic projection of the second conductive sub-layer on the dielectric substrate at least partially overlap, and the flow directions of the currents of both are parallel.

In at least one embodiment provided by the present disclosure, when the first conductive structure includes the at least three first conductive sub-layers and the second conductive structure includes one of the second conductive sub-layers,
the first conductive structure includes an even number of the first conductive sub-layers; and the orthographic projections of at least two of the first conductive sub-layers on the dielectric substrate at least partially overlap, and the flow directions of the currents of both are the same.

In at least one embodiment provided by the present disclosure, the orthographic projection of at least one of the first conductive sub-layers on the dielectric substrate and the orthographic projection of the second conductive sub-layer on the dielectric substrate at least partially overlap, and the flow directions of the currents of both are the same.

In at least one embodiment provided by the present disclosure, when the first conductive structure includes the at least three first conductive sub-layers and the second conductive structure includes one of the second conductive sub-layers,
the first conductive structure includes an odd number of the first conductive sub-layers; and the orthographic projections of at least two of the first conductive sub-layers on the dielectric substrate at least partially overlap, and the flow directions of the currents of both are opposite.

In at least one embodiment provided by the present disclosure, the orthographic projection of at least one of the first conductive sub-layers on the dielectric substrate and the orthographic projection of the second conductive sub-layer on the dielectric substrate at least partially overlap, and the flow directions of the currents of both are opposite.

In at least one embodiment provided by the present disclosure, the first conductive structure includes a first one of the first conductive sub-layers, a second one of the first conductive sub-layers, a third one of the first conductive sub-layers and a fourth one of the first conductive sub-layers disposed in sequence in a direction away from the dielectric substrate;
wherein the first one of the first conductive sub-layers includes a plurality of first wirings extending in a first direction and disposed in a second direction, the fourth one of the first conductive sub-layers includes a plurality of second wirings extending in the first direction and disposed in the second direction, the first direction and the second direction intersect, and the orthographic projections of the first wirings and the second wirings on the dielectric substrate at least partially overlap; and
the second one of the first conductive sub-layers includes a third wiring, the third one of the first conductive sub-layers includes a plurality of fourth wirings extending in a third direction and disposed in a fourth direction, the second conductive sub-layer includes a plurality of fifth wirings extending in the third direction and disposed in the fourth direction, the third direction and the fourth direction intersect, the orthographic projections of the fourth wirings and the fifth wirings on the dielectric substrate at least partially overlap, and the first direction and the third direction intersect.

In at least one embodiment provided by the present disclosure, the inductance structure includes N first wirings disposed in the same row and N second wirings disposed in the same row, wherein N is a positive integer, and N is greater than or equal to 1; the orthographic projections of an N^{th} one of the first wirings and an N^{th} one of the second wirings on the dielectric substrate overlap, and the flow directions of the currents of both are the same; and
every two of the connection electrodes are divided into one group as a connection electrode group, and the same connection electrode group is in contact with and connected to the same fifth wiring; the same connection electrode group includes a first connection electrode and a second connection electrode, wherein a region where the first connection electrode is located overlaps with an orthographic projection of a first end of the fourth wiring on the dielectric substrate, and a region where the second connection electrode is located overlaps with an orthographic projection of a second end of the fourth wiring on the dielectric substrate; and the flow directions of the currents of the first connection electrode and the second connection electrode in the same connection electrode group are opposite.

In at least one embodiment provided by the present disclosure, the inductance structure further includes N fourth wirings disposed in the same row and N+1 fifth wirings disposed in the same row; and the orthographic projections of an N^{th} one of the fourth wirings and an (N+1)^{th} one of the fifth wirings on the dielectric substrate overlap, and the flow directions of the currents of both are the same.

In at least one embodiment provided by the present disclosure, on the first surface, a second end of a first one of the first wirings and a second end of a first one of the second wirings are respectively electrically connected to a first end of a first one of the fourth wirings; a first end of a second one of the first wirings and a first end of a second one of the second wirings are respectively electrically connected to a second end of a first one of the fourth wirings; and

the second end of the N^{th} one of the first wirings and the second end of the N^{th} one of second wirings are respectively electrically connected to the first end of the N^{th} one of the fourth wirings; and the first end of the (N+1)^{th} one of the first wirings and the first end of the (N+1)^{th} one of the second wirings are respectively electrically connected to the second end of the NI one of the fourth wirings.

In at least one embodiment provided by the present disclosure, the inductance structure includes N+1 connection electrode groups disposed in the same row; a first end of the third wiring is electrically connected to an (N+1)^{th} one of the second connection electrodes; and a second end of the third wiring is respectively electrically connected to a first end of the first one of the first wirings and a first end of the first one of the second wirings; and

the first end of the first one of the first wirings and the first end of the first one of the second wirings are electrically connected to a first one of the second connection electrodes, respectively; the first end of the first one of the first wirings and the first end of the first one of the second wirings are electrically connected to a second one of the first connection electrodes, respectively; a first end of the Ni one of the first wirings and a first end of the N^{th} one of the second wirings are electrically connected to an N^{th} one of the second connection electrodes, respectively; and the second end of the N^{th} one of the first wirings and the second end of the N^{th} one of the second wirings are electrically connected to an (N+1)^{th} one of the first connection electrodes, respectively.

In at least one embodiment provided by the present disclosure, the orthographic projection of the third wiring except the regions of the first end and the second end thereof on the dielectric substrate does not overlap with a region where the connection electrode group is located.

In at least one embodiment provided by the present disclosure, the inductance structure further includes N+1 fourth wirings disposed in the same row and N+1 fifth wirings disposed in the same row; and
the orthographic projections of an N^{th} one of the fourth wiring and an N^{th} one of the fifth wiring on the dielectric substrate overlap, and the flow directions of the currents of both are the same.

In at least one embodiment provided by the present disclosure, on the first surface, a second end of a first one of the fourth wirings is electrically connected to a first end of a first one of the first wirings and a first end of a first one of the second wirings, respectively; a first end of an (N+1)^{th} one of the fourth wirings is electrically connected to a second end of a N^{th} one of the first wirings and a second end of an N^{th} one of the second wirings, respectively; and a second end of the (N+1)^{th} one of the fourth wirings is electrically connected to a first end of an (N+1)^{th} one of the first wirings and a first end of an (N+1)^{th} one of the second wirings, respectively.

In at least one embodiment provided by the present disclosure, the inductance structure includes N+1 connection electrode groups disposed in the same row, a first end of the third wiring is electrically connected to an (N+1)^{th} one of the second connection electrode, and a second end of the third wiring is electrically connected to a first end of the first one of the fourth wirings.

In at least one embodiment provided by the present disclosure, the orthographic projections of each of the first wirings, each of the second wirings, each of the fourth wirings, and each of the fifth wirings on the dielectric substrate respectively overlaps with the orthographic projection of the third wiring on the dielectric substrate.

In at least one embodiment provided by the present disclosure, the first conductive structure includes a first one of the first conductive sub-layers, a third one of the first conductive sub-layers and a fourth one of the first conductive sub-layers disposed in sequence in a direction away from the dielectric substrate;
the first one of the first conductive sub-layers includes a plurality of first wirings extending in a first direction and disposed in a second direction, the fourth one of the first conductive sub-layers includes a plurality of second wirings extending in the first direction and disposed in the second direction, the first direction and the second direction intersect, and the orthographic projections of the first wirings and the second wirings on the dielectric substrate at least partially overlap; and
the third one of the first conductive sub-layers includes a plurality of fourth wirings extending in a third direction and disposed in a fourth direction, the second conductive sub-layer includes a plurality of fifth wirings extending in the third direction and disposed in the fourth direction, the third direction and the fourth direction intersect, the orthographic projections of the fourth wirings and the fifth wirings on the dielectric substrate at least partially overlap, and the first direction and the third direction intersect.

In at least one embodiment provided by the present disclosure, the inductance structure includes N first wirings disposed in the same row, N second wirings disposed in the same row, N+1 fourth wirings disposed in the same row, and N+1 fifth wirings disposed in the same row; wherein N is a positive integer, and N is greater than or equal to 1;
orthographic projections of an N^{th} one of the first wirings and an N^{th} one of the second wirings on the dielectric substrate overlap, and the flow directions of the currents of both are opposite; orthographic projections of an N^{th} one of the fourth wirings and an N^{th} one of the fifth wirings on the dielectric substrate overlap, and the flow directions of the currents of both are opposite; and
every two of the connection electrodes are divided into one group as a connection electrode group, and the same connection electrode group is in contact with and connected to the same fifth wiring; the same connection electrode group includes a first connection electrode and a second connection electrode, wherein a region where the first connection electrode is located overlaps with orthographic projections of first ends of the fourth wirings on the dielectric substrate, and a region where the second connection electrode is located overlaps with orthographic projections of second ends of the fourth wirings on the dielectric substrate; and the flow directions of the currents of the first connection electrode and the second connection electrode in the same connection electrode group are opposite.

In at least one embodiment provided by the present disclosure, a first one of the first connection electrodes is electrically connected to the first end of the first one of the fourth wirings and the first end of the first one of the first wirings, respectively; the second end of the first one of the fourth wirings is electrically connected to a first one of the second connection electrodes; a second end of the first one of the first wirings is electrically connected to a second one of the second connection electrodes and a first end of the first one of the second wirings, respectively; the second end of the first one of the second wirings is electrically connected to the first end of the first one of the first wirings and the first end of the first one of the fourth wirings, respectively; and

an N^{th} one of the first connection electrodes is electrically connected to a first end of the N^{th} one of the fourth wirings and a first end of the N^{th} one of the first wirings respectively; a second end of the N^{th} one of the fourth wirings is electrically connected to an N^{th} one of the second connection electrodes; a second end of the No one of the first wirings is electrically connected to an (N+1)^{th} one of the second connection electrodes and a first end of the N^{th} one of the second wirings respectively; and a second end of the N^{th} one of the second wirings is electrically connected to the first end of the N^{th} one of the first wirings and the first end of the N^{th} one of the fourth wirings, respectively.

In at least one embodiment provided by the present disclosure, the inductance structure further includes a first insulating layer, a second insulating layer, a third insulating layer, a first protective layer and a second protective layer;
the first insulating layer is located between the first one of the first conductive sub-layers and the second one of the first conductive sub-layers; the second insulating layer is located between the second one of the first conductive sub-layers and the third one of the first conductive sub-layers; the third insulating layer is located between the third one of the first conductive sub-layers and the fourth one of the first conductive sub-layers; and
the first protective layer covers the fourth one of the first conductive sub-layers, and the second protective layer covers the second conductive sub-layer.

In at least one embodiment provided by the present disclosure, the inductance structure further includes a first insulating layer, a third insulating layer, a first protective layer and a second protective layer;
the first insulating layer is located between the first one of the first conductive sub-layers and the third one of the first conductive sub-layers; the third insulating layer is located between the third one of the first conductive sub-layers and the fourth one of the first conductive sub-layers; and
the first protective layer covers the fourth one of the first conductive sub-layers, and the second protective layer covers the second conductive sub-layer.

In at least one embodiment provided by the present disclosure, thickness ranges of the first conductive sub-layer and the second conductive sub-layer are 1 μm to 10 μm.

In at least one embodiment provided by the present disclosure, the connection electrode includes a metal material; or
the connection electrode includes a resin and a metal material wrapping the resin.

In at least one embodiment provided by the present disclosure, at least one of the first wirings, the second wirings, the fourth wirings and the fifth wirings includes a plurality of sub-wirings disposed in parallel, a gap is provided between two adjacent sub-wirings, and a line width of each sub-wiring is roughly the same.

In at least one embodiment provided by the present disclosure, an angle between the first direction and the third direction is an acute angle.

In at least one embodiment provided by the present disclosure, the third wiring includes a plurality of sub-wirings disposed in parallel, a gap is provided between two adjacent sub-wirings, and a line width of each sub-wiring is roughly the same.

In at least one embodiment provided by the present disclosure, the line width of the third wiring is less than the line widths of the first wirings, the second wirings, and the fourth wirings.

In a second aspect, embodiments of the present disclosure provide a filter, including at least one inductance structure as described in any one of the first aspect and at least one capacitor.

The above description is only an overview of the technical solution of the present disclosure. In order to have a clearer understanding of the technical means of the present disclosure, it can be implemented according to the content of the specification. In order to make the above and other purposes, features, and advantages of the present disclosure more obvious and easier to understand, the specific implementation methods of the present disclosure are listed below.

### BRIEF DESCRIPTION OF THE DRAWINGS

In order to provide a clearer explanation of the technical solutions in the embodiments of the present disclosure or related technologies, a brief introduction will be given below to the accompanying drawings required in the embodiments or related technical descriptions. It is obvious that the accompanying drawings in the following description are some embodiments of the present disclosure. For those skilled in the art, other accompanying drawings can be obtained based on these drawings without creative labor. It should be noted that the proportions in the accompanying drawings are only for illustrative purposes and do not represent the actual proportions.

FIG. 1 and FIG. 3 are both schematic structural diagrams of a first type of an inductance structure according to an embodiment of the present disclosure;

FIG. 2 is a schematic diagram of an intermediate structure of the inductance structure of FIG. 1 when a fourth one of first conductive sub-layers is not provided;

FIG. 4 is a right side view of FIG. 1;

FIG. 5 is a top view of a first conductive structure of the inductance structure shown in FIG. 1;

FIG. 6 is a top view of FIG. 1;

FIG. 7 is a schematic diagram of an intermediate structure of a second type of an inductance structure according to an embodiment of the present disclosure when a third one of first conductive sub-layers and a fourth one of the first conductive sub-layers are not provided;

FIG. 8 is a schematic structural diagram of a second type of an inductance structure according to an embodiment of the present disclosure;

FIG. 9 is a right side view of FIG. 8;

FIG. 10 is a top view of a first conductive structure of the inductance structure shown in FIG. 8;

FIG. 11 is a schematic diagram of an intermediate structure of a third type of an inductance structure according to an embodiment of the present disclosure when a fourth one of the first conductive sub-layers is not provided;

FIG. 12 is a schematic structural diagram of a third type of an inductance structure according to an embodiment of the present disclosure;

FIG. 13 is a top view of a first conductive structure of the inductance structure shown in FIG. 12;

FIG. 14 is a right side view of FIG. 12;

FIG. 15 is a schematic structural view of a filter; and

FIG. 16A to FIG. 16H are schematic diagrams of intermediate structures during the fabrication of an inductance structure according to embodiments of the present disclosure.

### DETAILED DESCRIPTION

The following will provide a clear and complete description of the technical solution in the embodiments of the present disclosure in conjunction with the accompanying drawings of the present disclosure. Obviously, the described embodiments are a part of the embodiments of the present disclosure, not all of them. Based on the embodiments in the present disclosure, all other embodiments obtained by persons skilled in the art without creative labor fall within the scope of protection of the present disclosure.

In the embodiments of the present disclosure, the use of words such as “first”, “second”, “third”, “fourth”, etc. to distinguish similar or identical items with similar functions and effects is only for the purpose of clearly describing the technical solution of the embodiments of the present disclosure, and cannot be understood as indicating or implying relative importance or implying the number of indicated technical features.

In the embodiments of the present disclosure, the terms “up”, “down”, etc. indicate orientation or positional relationships based on the orientation or positional relationships shown in the drawings, only for the convenience of describing the present disclosure and simplifying the description, rather than indicating or implying that the device or component referred to must have a specific orientation, be constructed and operated in a specific orientation, and therefore cannot be understood as a limitation on the present disclosure.

In the description of the specification, the terms “one embodiment,” “some embodiments,” “exemplary embodiments,” “examples,” “specific examples,” or “some examples,” etc. are intended to indicate that specific features, structures, materials, or features related to the embodiment or example are included in at least one embodiment or example of the present disclosure. The schematic representation of the above terms may not necessarily refer to the same embodiment or example. Furthermore, the specific features, structures, materials, or features described may be included in any one or more embodiments or examples in any appropriate manner.

In the embodiments of the present disclosure, “plurality of” means two or more, and “at least one” means one or more, unless otherwise specified.

The features used in the embodiments of the present disclosure, such as “parallel,” “vertical,” and “same,” all include strictly defined features such as “parallel,” “vertical,” and “same,” as well as situations where “roughly parallel,” “roughly vertical,” and “roughly identical,” contain certain tolerances, considering the tolerances related to measurement and specific quantities of measurement (such as limitations of measurement systems), which indicates that they are within the acceptable deviation range for a specific value determined by persons skilled in the art. For example, “roughly” can be expressed within one or more standard deviations, or within 10% or 5% of the value.

Unless the context otherwise requires, in the entire specification and claims, the term “including/comprising” is interpreted as open and inclusive, meaning “including, but not limited to”.

The term “same layer” in the embodiment of the present disclosure refers to the relationship between multiple film layers formed by the same material after undergoing the same step (such as a one-step patterning process). The term “same layer” here does not always refer to multiple film layers with the same thickness or multiple film layers with the same height in the cross-sectional view. The polygons in the specification are not strictly defined, but can be approximate triangles, parallelograms, trapezoids, pentagons, or hexagons, and may have some small deformations caused by tolerances.

With the rapid development of electronic communication technology, 5G technology is continuously popularized, the frequency range of signal transmission becomes wider and wider, which greatly improves the speed of signal transmission between devices and promotes the rapid development of social information transmission. Meanwhile, a variety of new process technology continues to emerge. With the rapid development of integration technology, more and more devices are integrated in the small size of chips. On the one hand, it greatly reduce the size of the electronic device. On the other hand, it enriches various media functions within the device. Device dimensions allow iteration from macroscopic centimeter dimensions to microscopic micrometer or even nanometer dimensions.

The 5G technology firstly expands the range of the signal transmission, and a large increase in the signal frequency places higher demands on the electronics within the device, especially in common mobile terminals. Secondly, the increase in the signal frequency requires electronic components to transmit signals better and faster, requiring further increases in device power ratings. It is a new goal for achieving higher-performance devices per unit volume.

The development of IPD (Integrated Passive Device) technology has greatly improved the integration of devices and become a manufacturing method that can match the development requirements of electronic communication technology. This process changes the conventional process dimensions and places higher demands on the design of passive devices. The traditional inductance of copper wire loop is replaced by the planar spiral inductance. With the development of substrate processing technology, the inductance of 3D (three-dimensional) stereoscopic structure has been greatly developed. This type of passive device can be used for both discrete devices and radio frequency (RF) modules. Therefore, the improvement of IPD device performance will contribute to the further development of RF technology.

Based on this, the embodiments of the present disclosure provide an inductance structure and a filter based on the IPD technology. The inductance structure includes a dielectric substrate, a first conductive structure disposed on a first surface, and a second conductive structure disposed on a second surface; the dielectric substrate is provided with a plurality of connection through-holes penetrating in a thickness direction thereof, connection electrodes are provided in the connection through-holes; the first conductive structure and the second conductive structure are electrically connected by the connection electrodes to form a coil of the inductance structure; one of the first conductive structure and the second conductive structure includes at least three sub-layers, and the other includes at least one sub-layer; and orthographic projections of the two sub-layers of the first conductive structure and the second conductive structure on the dielectric substrate at least partially overlap, and the flow directions of currents of the two sub-layers are roughly parallel. The embodiments of the present disclosure provide an inductance structure which, under the original preparation process conditions, can greatly increase the inductance value, increase the inductance density per unit volume and reduce the size of the inductance structure by means of changing the design, so that the inductance structure bas a wider and flexible application. Also, it does not increase the difficulty of the preparation process and the preparation cost while improving the performance of the inductance structure.

The inductance structure and filter provided by the embodiments of the present disclosure will be specifically described and explained with reference to the accompanying drawings.

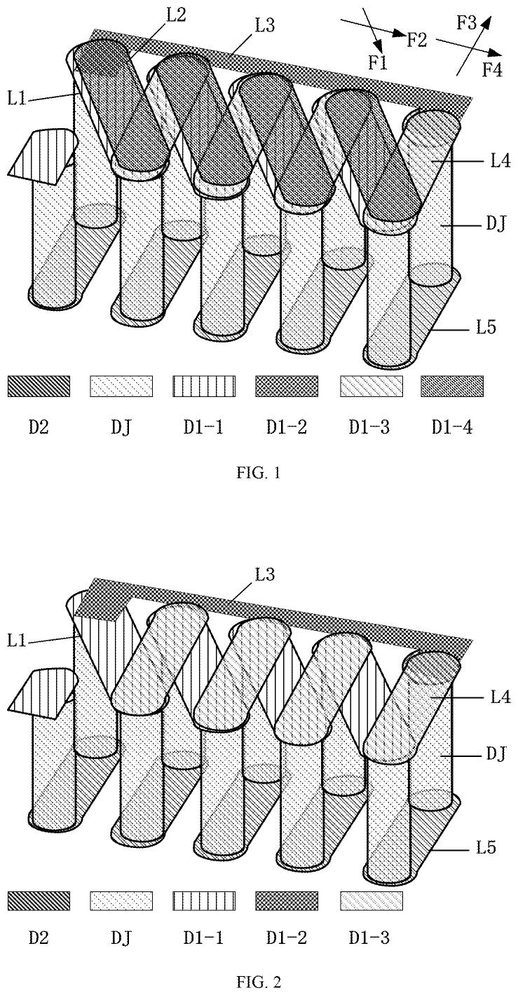

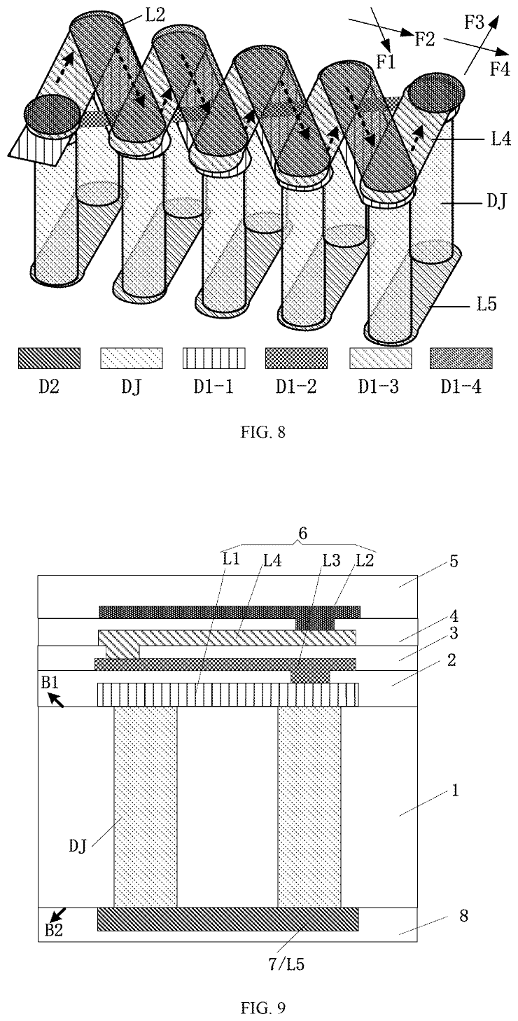

Embodiments of the present disclosure provide an inductance structure, as shown in FIG. 4, FIG. 9 and FIG. 14, including:
a dielectric substrate 1, wherein the dielectric substrate 1 is provided with a plurality of connection through-holes Via penetrating in a thickness direction thereof; connection electrodes DJ are disposed in the connection through-holes; the dielectric substrate 1 further includes a first surface B1 and a second surface B2 oppositely disposed in the thickness direction thereof;
a first conductive structure 6 disposed on the first surface B1; and
a second conductive structure 7 disposed on the second surface B2;
wherein the first conductive structure 6 and the second conductive structure 7 are electrically connected by the connection electrodes DJ so as to form a coil of the inductance structure; one of the first conductive structure 6 and the second conductive structure 7 includes at least three sub-layers and the other includes at least one sub-layer (for example, as shown in conjunction with FIG. 1 and FIG. 4, the first conductive structure 6 includes a sub-layer D1-1, a sub-layer D1-2, a sub-layer D1-3 and a sub-layer D1-4; the second conductive structure 7 includes a sub-layer D2); and the orthographic projections of two of the sub-layers in the first conductive structure 6 and the second conductive structure 7 on the dielectric substrate 1 at least partly overlap and the flow directions of the currents of both are roughly parallel.

The main material of the above-mentioned dielectric substrate 1 is an insulating material, and the specific material type of the above-mentioned dielectric substrate 1 is not limited herein.

In some embodiments, the main material of the dielectric substrate 1 may be a rigid material.

Exemplarily, the dielectric substrate 1 may be a standard silicon wafer with embedded chips, a high-resistivity silicon substrate, a glass substrate, a ceramic substrate or a low-K molding material with embedded chips in an eWLB (embedded wafer level ball grid array) packaging process.

In other embodiments, the main material of the dielectric substrate 1 may be a flexible material.

Exemplarily, the dielectric substrate 1 may be a polyimide (PI) substrate or a dibenzocyclobutene (BCB) substrate.

The size and thickness of the above-mentioned dielectric substrate 1 are not limited here.

Exemplarily, the thickness of the dielectric substrate 1 may range from 0.2 mm to 0.5 mm, for example, the thickness of the dielectric substrate 1 may be 0.3 mm, 0.4 mm.

The above-mentioned multiple connection through-holes Via refers to two or more connection through-holes Via. Herein, the connection through-holes Via are at least filled with a conductive material so as to form the connection electrodes DJ. Therefore, the structure of the connection through-holes Via are not directly reflected in the drawings provided in the embodiments of the present disclosure.

The specific number of the above-mentioned connection through-holes Via (or connection electrodes DJ) is not limited herein.

In some embodiments, the number of connection through-holes Via (or connection electrodes DJ) described above is even, so that a loop is formed between the first conductive structure 6 and the second conductive structure 7 on both sides of the dielectric substrate 101. For example, the number of the above-mentioned connection through-holes Via (or connection electrodes DJ) may be two, four, six, eight, etc.

The three-dimensional shape of the connection through-holes Via is not limited herein. Exemplarily, the three-dimensional shape of the above-mentioned connection through-holes Via may be columnar, for example, cylindrical, or prismatic. Exemplarily, the three-dimensional shape of the connection through-holes Via may be a truncated cone or a truncated pyramid.

The shape of the cross-sectional pattern of the connection through-holes Via is not limited herein. Exemplarily, the cross-sectional pattern of the connection through-holes Via may be quadrilateral in shape, e.g., rectangular, square, trapezoidal.

Here, the number and shape of the connection electrodes DJ are related to the number and shape of the connection through-holes Via, which will not be described in detail herein.

The size of the planar pattern of the connection through-holes Via is not limited herein. For example, the planar pattern of the connection through-holes Via is roughly circular, among them, the circular shape has a diameter ranging from 30 μm to 100 μm. For example, the diameter of the circle is 33 μm, 35 μm, 40 μm, 43 μm, 45 μm, 48 μm, 55 μm, 60 μm, 63 μm, 65 μm, 68 μm, 70 μm, 75 μm, 78 μm, 80 μm, 86 μm, 88 μm, 90 μm, 93 μm, 95 μm, or 98 μm.

Exemplarily, when the plane pattern of the connection through-holes Via is a polygon, the size of the largest diagonal of the polygon ranges from 30 μm to 100 μm. For example, the size of the largest diagonal of the polygon is 33 μm, 35 μm, 40 μm, 43 μm, 45 μm, 48 μm, 55 μm, 60 μm, 63 μm, 65 μm, 68 μm, 70 μm, 75 μm, 78 μm, 80 μm, 86 μm, 88 μm, 90 μm, 93 μm, 95 μm or 98 μm.

Exemplarily, when the three-dimensional shape of the connection through-holes Via is a truncated cone shape or a truncated pyramid shape, the sizes of the plane pattern of an upper opening and a lower opening of the connection through-holes Via are different. In this case, the size of the plane pattern of the upper opening and the lower opening ranges from 30 μm to 100 μm.

For example, the three-dimensional shape of the connection through-holes Via may be a shape in which two truncated cone-shaped or truncated pyramid-shaped structures are spliced together (an hourglass-shaped shape). Namely, the three-dimensional stereoscopic shape of the connection through-holes Via exhibits that the sizes of the upper opening and the lower opening are both greater than the size of the plane pattern of the middle region. It is understood that, at this time, the cross-sectional figure has a shape in which two trapezoids are spliced together, wherein the upper base of the upper trapezoid is spliced together with the upper base of the lower trapezoid, and the lower bases of the two trapezoids are respectively located at both sides.

In an exemplary embodiment, the first surface B1 and the second surface B2 may be parallel (roughly parallel) to each other. Exemplarily, both the first surface B1 and the second surface B2 may be planar.

The shape of the specific conductive pattern of the first conductive structure 6 and the second conductive structure 7 described above is not limited herein. Exemplarily, the orthographic projections of the conductive pattern in the first conductive structure 6 and the conductive pattern in the second conductive structure 7 on the dielectric substrate 1 at least partially overlap, where “at least partially overlapping” includes but is not limited to partially overlapping and completely overlapping.

The specific materials of the first conductive structure 6 and the second conductive structure 7 described above are not limited herein. Exemplarily, the material of the first conductive structure 6 and the second conductive structure 7 may include any one of copper, silver, aluminum, nickel, molybdenum and titanium or a combination of several metals disposed in a stack.

In an exemplary embodiment, one of the first conductive structure 6 and the second conductive structure 7 includes at least three sub-layers and the other includes at least one sub-layer, including, but not limited to, the following:
firstly, the first conductive structure 6 includes at least three sub-layers and the second conductive structure 7 includes at least one sub-layer.

For example, the first conductive structure 6 includes at least three sub-layers and the second conductive structure 7 includes one sub-layer. At this time, the sub-layers in the first conductive structure 6 are electrically connected to each other, to serve as a first conductive line.

As another example, the first conductive structure 6 includes at least three sub-layers and the second conductive structure 7 includes at least three sub-layers. At this time, the sub-layers in the first conductive structure 6 are electrically connected to each other, to serve as a first wire. The sub-layers in the second conductive structure 7 are electrically connected to each other, to serve as a second wire. The first wire and the second wire are electrically connected by the connection electrode DJ, to form a conductive loop and constitute a coil of the inductance structure.

Secondly, the second conductive structure 7 includes at least three sub-layers and the first conductive structure 6 includes at least one sub-layer.

For example, the second conductive structure 7 includes at least three sub-layers and the first conductive structure 6 includes one sub-layer. At this time, the sub-layers in the second conductive structure 7 are electrically connected to each other, to serve as the second wire.

As another example, the second conductive structure 7 includes at least three sub-layers and the first conductive structure 6 includes at least three sub-layers. At this time, the sub-layers in the first conductive structure 6 are electrically connected to each other, to serve as the first wire. The sub-layers in the second conductive structure 7 are electrically connected to each other, to each other as the second wire. The first wire and the second wire are electrically connected by the connection electrode DJ, to form a conductive loop and constitute a coil of the inductance structure.

Exemplarily, the material of the at least one sub-layer may include any one of copper, silver, aluminum, nickel, molybdenum and titanium or a combination of several metals disposed in a stack.

In some embodiments, the material of the at least one sub-layer may include a layer of Molybdenum-nickel-titanium alloy (MoNiTi), a layer of copper metal, and a layer of molybdenum-niobium alloy (MoNb) that are stacked in sequence. The layer of molybdenum-nickel-titanium alloy increases the nucleation density of the copper metal grains in the electroplating process. The layer of molybdenum-niobium alloy serves to prevent oxidation of the copper metal.

In other embodiments, the at least one sub-layer may include a molybdenum-niobium alloy layer, a copper metal layer, and a protective layer that are stacked in sequence. The protective layer may include any one of copper-nickel alloy (CuNi), nickel, or Indium Tin Oxide (ITO). The molybdenum-niobium alloy layer serves to improve the adhesion between the copper metal and the film layer on a side close to the dielectric substrate 1. The protective layer serves to prevent the oxidation of the copper metal.

In some embodiments, the thickness of the at least one sub-layer described above may range from 0.5 to 10 μm. For example, the thickness may be 0.5 μm, 1 μm, 1.8 μm, 2.7 μm, or 10 μm.

In other embodiments, the thickness of the at least one sub-layer may range from 1.5 μm to 7 μm. For example, the thickness may be 1.5 μm, 2 μm, 4 μm, 6.5 μm or 7 μm.

Among them, the orthographic projections of two sub-layers of the first conductive structure 6 and the second conductive structure 7 on the dielectric substrate 1 at least partially overlap, and the flow directions of the currents of both are roughly parallel, including but not limited to the following cases.

In the first case, the first conductive structure 6 includes at least three sub-layers. The orthographic projections of the two sub-layers in the first conductive structure 6 on the dielectric substrate 1 at least partly overlap, and the flow directions of the currents of both are roughly parallel.

In the second case, the second conductive structure 7 includes at least three sub-layers. The orthographic projections of the two sub-layers in the second conductive structure 7 on the dielectric substrate 1 at least partly overlap, and the flow directions of the currents of both are roughly parallel.

In the third case, the first conductive structure 6 includes at least three sub-layers and the second conductive structure 7 includes at least one sub-layer. Alternatively, the first conductive structure 6 includes at least one sub-layer and the second conductive structure 7 includes at least three sub-layers. The orthographic projections of one sub-layer of the first conductive structure 6 and one sub-layer of the second conductive structure 7 on the dielectric substrate 1 at least partly overlap, and the flow directions of the currents are roughly parallel.

It should be noted that the above-mentioned “at least partial overlap” includes partially overlapping or completely overlapping.

Among them, the roughly parallel flow directions of the currents may include that the current flows in the identical direction (i.e., the same direction) or in opposite directions.

Theoretical calculation formulas for inductance and mutual inductance are provided below:

$$L\_Z = \frac{μ L}{2 π ( ln ( \frac{2 L}{W + t} ) + \frac{W + t}{3 L} + 0.5 )} \qquad Formula ( 1 )$$

$${L}_{M} = \frac{μ L}{2 π ( arcsinh ( \frac{L}{D} ) + ( D − \sqrt{{D}^{2} + {L}^{2}} ) / L )} \qquad Formula ( 2 )$$

where L-Z represents the inductance value of the inductance structure; L_{M} represents the mutual inductance value in the inductance structure; and the increase of the mutual inductance value will increase the overall inductance value of the inductance structure.

In the above-mentioned formula (1), the above-mentioned μ is the magnetic permeability of the material of the dielectric substrate 1. Herein, the wire provided in the first conductive structure 6 is referred to as a first wire. The wire provided in the second conductive structure 7 is referred to as a second wire. The connection electrode DJ is a third wire. With regard to the first conductive structure 6 and the second conductive structure 7, L represents the effective length of the wire, W represents the width of the wire, and t represents the thickness of the wire. As for the connection electrode DJ, taking the columnar connection electrode DJ as an example, W represents the diameter of the circle when the plane pattern is circular, t represents the height of the columnar connection electrode DJ, and L also represents the diameter of the circle.

In the above-mentioned formula (2), the above-mentioned u is the magnetic permeability of the material of the dielectric substrate 1. Herein, the wire provided in the first conductive structure 6 is referred to as the first wire. The wire provided in the second conductive structure 7 is referred to as the second wire. The connection electrode DJ is the third wire. L represents the effective length of the wire, W represents the width of the wire, t represents the thickness of the wire, and D represents the spacing of the wires. With regard to the connection electrode DJ, taking the columnar connection electrode DJ as an example, W represents the diameter of the circle when the plane pattern is circular, t represents the height of the columnar connection electrode DJ, L also represents the diameter of the circle, and D represents the spacing between the connection electrodes DJ.

It should be noted that when the current directions of the two conductive structures are identical, the larger the area of the overlapping region of the two is, the larger the mutual inductance is.

In an inductance structure provided by an embodiment of the present disclosure, with reference to FIG. 4 or FIG. 9 or FIG. 14, on the one hand, by providing that one of the first conductive structure 6 and the second conductive structure 7 includes at least three sub-layers, and the other includes at least one sub-layer (for example, as shown in conjunction with FIG. 1 and FIG. 4, the first conductive structure 6 includes a sub-layer D1-1, a sub-layer D1-2, a sub-layer D1-3 and a sub-layer D1-4; the second conductive structure 7 includes a sub-layer D2), it increases the number of conductive layers constituting the wire (coil), thereby extending the effective length of the coil forming the inductance structure, thereby increasing the inductance density of the inductance structure and increasing the inductance value. On the other hand, by providing that the orthographic projections of two sub-layers in the first conductive structure 6 and the second conductive structure 7 on the dielectric substrate 1 at least partially overlap, when the flow directions of the currents of both are the same, the mutual inductance of the inductance structure may be effectively increased, the inductance value of the inductance structure is further increased, and the performance of the inductance structure is improved. The application flexibility of the inductance structure is improved and the application field of the inductance structure is expanded on the condition that the size of inductance structure is basically unchanged.

In at least one embodiment provided by the present disclosure, as illustrated in conjunction with FIG. 1 and FIG. 4, the sub-layer in the first conductive structure 6 is referred to as a first conductive sub-layer D1 (e.g., a sub-layer D1-1, a sub-layer D1-2, a sub-layer D1-3, and a sub-layer D1-4). The sub-layer in the second conductive structure 7 is referred to as a second conductive sub-layer D2.

Herein, in some embodiments, the first conductive structure 6 includes at least three first conductive sub-layers D1, and the second conductive structure 7 includes at least three second conductive sub-layers D2.

Alternatively, in other embodiments, the first conductive structure 6 includes at least three first conductive sub-layers D1 and the second conductive structure 7 includes one second conductive sub-layer D2, as shown in connection with FIG. 1 and FIG. 4, in connection with FIG. 8 and FIG. 9, or in connection with FIG. 12 and FIG. 14.

In at least one embodiment provided by the present disclosure, the orthographic projections of at least two of the first conductive sub-layers D1 on the dielectric substrate 1 at least partially overlap, and the flow directions of the currents of both are parallel.

Exemplarily, there may be at least a partial overlap of the orthographic projections of the two of the first conductive sub-layers D1 on the dielectric substrate 1, and the flow directions of the currents of both are parallel.

For example, the orthographic projections of the two of the first conductive sub-layers D1 on the dielectric substrate 1 at least partially overlap, and the flow directions of the currents of both are identical (same).

As another example, the orthographic projections of the two of the first conductive sub-layers D1 on the dielectric substrate 1 at least partially overlap, and the flow directions of the currents of both are opposite.

Exemplarily, there may be at least a partial overlap of the orthographic projections of the three of the first conductive sub-layers D1 on the dielectric substrate 1, and the flow directions of the currents of them are parallel.

For example, the orthographic projections of the first one and the second one of the first conductive sub-layers D1 on the dielectric substrate 1 at least partially overlap and the flow directions of the currents of both are identical (same). The orthographic projections of the second one and the third one of the first conductive sub-layers D1 on the dielectric substrate 1 at least partially overlap and the flow directions of the currents of both are opposite.

As another example, the orthographic projections of the three first conductive sub-layers D1 on the dielectric substrate 1 at least partially overlap and the flow directions of the currents of them are the same.

In at least one embodiment provided by the present disclosure, the orthographic projection of at least one first conductive sub-layer D1 on the dielectric substrate 1 and the orthographic projection of the second conductive sub-layer D2 on the dielectric substrate 1 at least partially overlap, and the flow directions of the currents of both are parallel.

Exemplarily, there may be at least a partial overlap of the orthographic projection of the first conductive sub-layer D1 on the dielectric substrate 1 and the orthographic projection of the second conductive sub-layer D2 on the dielectric substrate 1, and the flow directions of the currents of both are parallel.

For example, the orthographic projection of one first conductive sub-layer D1 on the dielectric substrate 1 and the orthographic projection of the second conductive sub-layer D2 on the dielectric substrate 1 at least partially overlap, and the flow directions of the currents of both are the same.

For example, there may be orthographic projections of the two of the first conductive sub-layers D1 on the dielectric substrate 1 at least partially overlapping with the orthographic projection of the second conductive sub-layer D2 on the dielectric substrate 1, and the flow directions of the currents of them parallel.

For example, the orthographic projection of one of the two first conductive sub-layers D1 on the dielectric substrate 1 and the orthographic projection of the second conductive sub-layer D2 on the dielectric substrate 1 at least partially overlap, and the flow directions of the currents of both are identical (same). The orthographic projection of the other one on the dielectric substrate 1 and the orthographic projection of the second conductive sub-layer D2 on the dielectric substrate 1 at least partially overlap, and the flow directions of the currents of both are opposite.

As another example, the orthographic projection of the two of the first conductive sub-layers D1 on the dielectric substrate 1 and the orthographic projection of the second conductive sub-layer D2 on the dielectric substrate 1 at least partially overlap, and, and the flow directions of the currents of them are the same.

In at least one embodiment provided by the present disclosure, in the case where the first conductive structure 6 includes at least three first conductive sub-layers D1 and the second conductive structure 7 includes one second conductive sub-layer D2, when the first conductive structure 6 includes an even number of first conductive sub-layers D1,
in some examples, the orthographic projections of at least two of the first conductive sub-layers D1 on the dielectric substrate 1 at least partially overlap, and the flow directions of the currents of both are the same; and
in other examples, the orthographic projection of the at least one first conductive sub-layer D1 on the dielectric substrate and the orthographic projection of the second conductive sub-layer D2 on the dielectric substrate at least partially overlap, and the flow directions of the currents of the both are the same.

Exemplarily, the first conductive structure 6 includes four first conductive sub-layers D1, six first conductive sub-layers D1, eight first conductive sub-layers D1, or ten first conductive sub-layers D1.

In the inductance structure provided by the embodiments of the present disclosure, by providing that one of the first conductive structure 6 and the second conductive structure 7 includes at least three sub-layers, and the other includes at least one sub-layer (for example, as shown in conjunction with FIGS. 1 and 4, the first conductive structure 6 includes a sub-layer D1-1, a sub-layer D1-2, a sub-layer D1-3 and a sub-layer D1-4; the second conductive structure 7 includes a sub-layer D2), it increases the number of conductive layers constituting the wire (coil), thereby extending the effective length of the coil forming the inductance structure, thereby increasing the inductance density of the inductance structure and increasing the inductance value.

In addition, when the first conductive structure 6 includes an even number of first conductive sub-layers D1, by providing that the orthographic projections of two sub-layers in the first conductive structure 6 and the second conductive structure 7 on the dielectric substrate 1 at least partially overlap, when the flow directions of the currents of both are the same, the mutual inductance of the inductance structure may be effectively increased, the inductance value of the inductance structure is further increased, and the performance of the inductance structure is improved. The application flexibility of the inductance structure is improved and the application field of the inductance structure is expanded on the condition that the size of inductance structure is basically unchanged.

In at least one embodiment provided by the present disclosure, in the case where the first conductive structure 6 includes at least three first conductive sub-layers D1 and the second conductive structure 7 includes one second conductive sub-layer D2, when the first conductive structure 6 includes an odd number of first conductive sub-layers D1,
in some examples, the orthographic projections of the at least two of the first conductive sub-layers D1 on the dielectric substrate 1 at least partially overlap, and the flow directions of the currents of both are opposite.

In other examples, the orthographic projection of the at least one first conductive sub-layer D1 on the dielectric substrate 1 and the orthographic projection of the second conductive sub-layer D2 on the dielectric substrate 1 at least partially overlap, and the flow directions of the currents of both are opposite.

Exemplarily, the first conductive structure 6 includes three first conductive sub-layers D1, five first conductive sub-layers D1, seven first conductive sub-layers D1, nine first conductive sub-layers D1, or eleven first conductive sub-layers D1, etc.

In the inductance structure provided in the embodiments of the present disclosure, when the first conductive structure 6 includes the odd number of first conductive sub-layers D1, by providing that one of the first conductive structure 6 and the second conductive structure 7 includes at least three sub-layers, and the other includes at least one sub-layer (for example, as shown in conjunction with FIGS. 1 and 4, the first conductive structure 6 includes a sub-layer D1-1, a sub-layer D1-2, a sub-layer D1-3 and a sub-layer D1-4; the second conductive structure 7 includes a sub-layer D2), it increases the number of conductive layers constituting the wire (coil), thereby extending the effective length of the coil forming the inductance structure, thereby increasing the inductance density of the inductance structure, increasing the inductance value, and improving the performance of the inductance structure. The application flexibility of the inductance structure is improved and the application field of the inductance structure is expanded on the condition that the size of inductance structure is basically unchanged.

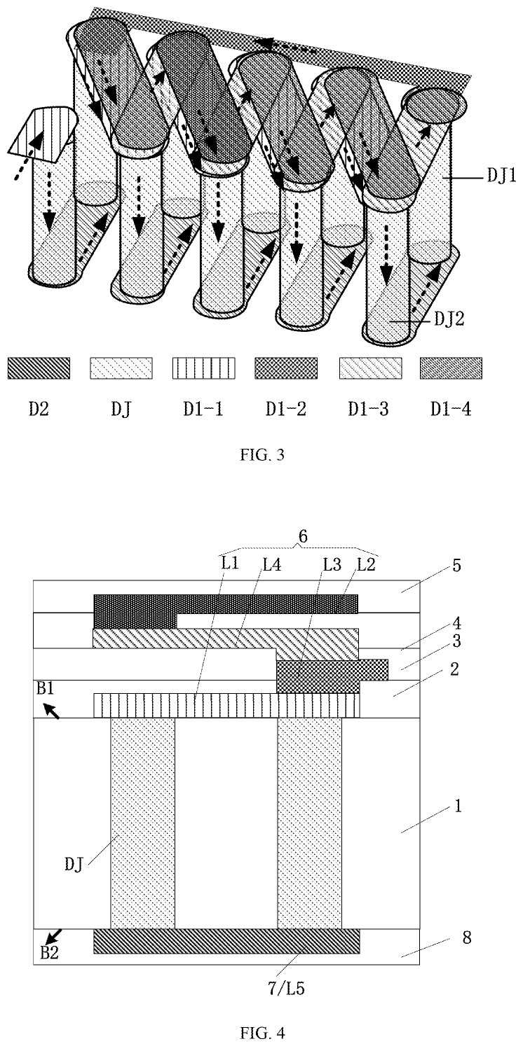

In at least one embodiment provided in the present disclosure, as shown in conjunction with FIG. 1, FIG. 2, FIG. 3 and FIG. 4, or as shown in conjunction with FIG. 7, FIG. 8 and FIG. 9, the first conductive structure 6 includes a first one of the first conductive sub-layers D1-1, a second one of the first conductive sub-layers D1-2, a third one of the first conductive sub-layers D1-3 and a fourth one of the first conductive sub-layers D1-4 which are successively disposed in a direction away from the dielectric substrate 1.

It should be noted that FIG. 4 is a right side view of the inductance structure shown in FIG. 3. The same inductance structure is depicted in FIG. 1 and FIG. 3. In order to avoid marking too many and creating confusion, the flow direction of the current for each wiring in the inductance structure is marked in FIG. 3.

Herein, as shown in conjunction with FIG. 1, FIG. 2, FIG. 3 and FIG. 4, or as shown in conjunction with FIG. 7, FIG. 8 and FIG. 9, a first one of the first conductive sub-layers D1-1 includes a plurality of first wirings L1 extending in a first direction F1 and disposed in a second direction F2. A fourth one of the first conductive sub-layers D1-4 includes a plurality of second wirings L2 extending in the first direction and disposed in the second direction. The first direction F1 and the second direction F2 intersect. The orthographic projections of the first wiring L1 and the second wiring L2 on the dielectric substrate 1 at least partially overlap.

A second one of the first conductive sub-layers D1-2 includes a third wiring L3. A third one of the first conductive sub-layer D1-3 includes a plurality of fourth wirings L4 extending along the third direction F3 and arranged along a fourth direction F4. The second conductive sub-layer D2 includes a plurality of fifth wirings L5 extending along the third direction F3 and arranged along the fourth direction F4. The third direction F3 and the fourth direction F4 intersect. The orthographic projections of the fourth wiring L4 and the fifth wiring L5 on the dielectric substrate 1 at least partially overlap. The first direction F1 and the third direction F3 intersect.

In an exemplary embodiment, the materials of the first one of the first conductive sub-layers D1-1, the second one of the first conductive sub-layers D1-2, the third one of the first conductive sub-layers D1-3, and the fourth one of the first conductive sub-layers D1-4 may each include any one of copper, silver, aluminum, nickel, molybdenum, and titanium, or a combination of several metals disposed in a stack.

Exemplarily, the material of at least one of the first conductive sub-layers D1 includes a layer of Molybdenum-nickel-titanium alloy (MoNiTi), a layer of copper metal, and a layer of molybdenum-niobium alloy (MoNb), that are stacked in sequence. The layer of molybdenum-nickel-titanium alloy increases the nucleation density of the copper metal grains in the electroplating process. The layer of molybdenum-niobium alloy serves to prevent oxidation of the copper metal.

Exemplarily, the material of the at least one first conductive sub-layer D1 may include a molybdenum-niobium alloy layer, a copper metal layer, and a protective layer that are sequentially stacked. The protective layer may include any one of copper-nickel alloy (CuNi), nickel, or Indium Tin Oxide (ITO). The molybdenum-niobium alloy layer serves to improve the adhesion between the copper metal and the film layer on a side close to the dielectric substrate 1. The protective layer serves to prevent the oxidation of the copper metal.

It is not limited herein whether the materials of the above-mentioned first one of the first conductive sub-layers D1-1, second one of the first conductive sub-layers D1-2, third one of the first conductive sub-layers D1-3 and fourth one of the first conductive sub-layers D1-4 are the same, and may be determined according to the design requirements for the conductivity of the inductance structure.

It is not limited here whether the lengths and widths (also referred to as line widths, Width) of the first wiring L1, the second wiring L2, the third wiring L3, the fourth wiring L4 and the fifth wiring L5 are the same.

In some embodiments, the first wiring L1 and the second wiring L2 have the same length.

In some embodiments, the fourth wiring L4 and the fifth wiring L5 have the same length.

In some embodiments, the length of the third wiring L3 is greater than the lengths of the first wiring L1, the second wiring L2, the fourth wiring L4, and the fifth wiring L5.

In some examples, the line widths of the first wiring L1 and the second wiring L2 are the same.

In some examples, the line widths of the fourth wiring L4 and the fifth wiring L5 are the same.

In some examples, the line width of the third wiring L3 is less than the line widths of the first wiring L1, the second wiring L2, the fourth wiring L4, and the fifth wiring L5.

There is no limitation on whether the thicknesses of the first wiring L1, the second wiring L2, the third wiring L3, the fourth wiring L4, and the fifth wiring L5 are the same.

In some examples, at least some of the first wiring L1, the second wiring L2, the third wiring L3, the fourth wiring L4, and the fifth wiring L5 have approximately the same thickness.

In some examples, at least some of the first wiring L1, the second wiring L2, the third wiring L3, the fourth wiring L4, and the fifth wiring L5 may include straight lines;
alternatively, at least some of the first wiring L1, the second wiring L2, the third wiring L3, the fourth wiring L4, and the fifth wiring L5 may include ares;
alternatively, at least some of the first wiring L1, the second wiring L2, the third wiring L3, the fourth wiring L4, and the fifth wiring L5 may include a broken line segment formed by straight line segments; and
alternatively, at least some of the first wiring L1, the second wiring L2, the third wiring L3, the fourth wiring L4, and the fifth wiring L5 may include a combination of straight lines and the arcs.

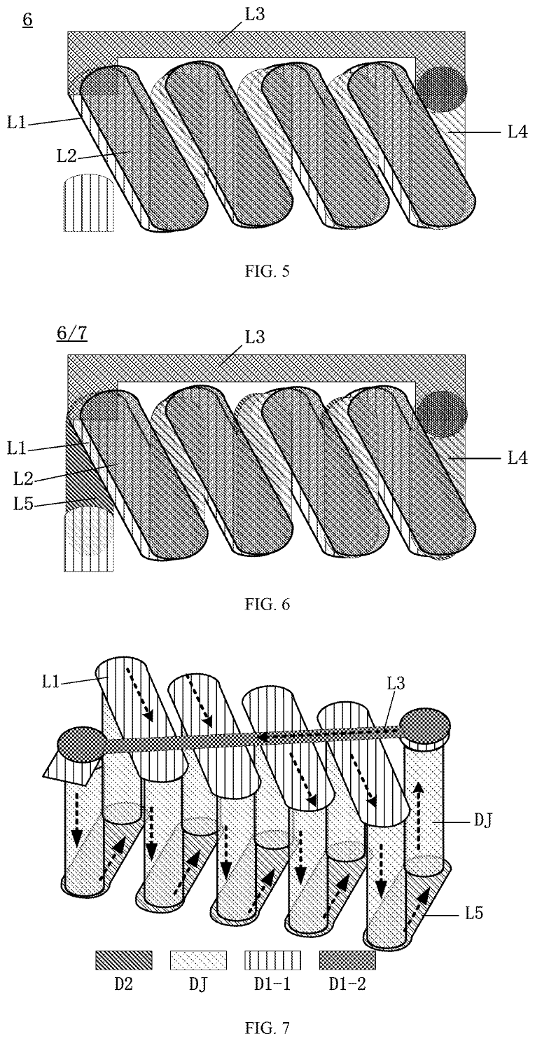

In at least one embodiment provided by the present disclosure, as shown in conjunction with FIG. 1, FIG. 2 and FIG. 3, the inductance structure includes N first wirings L1 disposed in the same row and N second wirings L2 disposed in the same row, where N is a positive integer, and N is greater than or equal to 1. As shown in FIG. 5, the orthographic projections of the N^{th} one of the first wirings L1 and the N one of the second wirings L2 on the dielectric substrate 1 overlap, and the flow directions of the currents of both are the same. Here, the direction pointed by a dotted arrow in FIG. 3 may be the flow direction of the current.

It should be noted that, in order to clearly embody the positional relationship of the orthographic projections of the N^{th} one of the first wirings L1 and the N^{th} one of the second wirings L2 on the dielectric substrate 1, in both FIG. 5 and FIG. 6, the orthographic projections of the N^{th} one of the first wirings L1 and the N^{th} one of the second wirings L2 on the dielectric substrate 1 partial overlap and are drawn as an example. In some embodiments, the orthographic projections of the N^{th} one of the first wirings L1 and the N^{th} one of the second wirings L2 on the dielectric substrate 1 may completely overlap.

In an exemplary embodiment, two connection electrodes DJ are divided into one group, and the same connection electrode group is in contact with and connected to the same fifth wiring L5. The same connection electrode group includes a first connection electrode DJ1 and a second connection electrode DJ2. The region where the first connection electrode DJ1 is located overlaps with the orthographic projection of the first end of the fourth wiring L4 on the dielectric substrate 1. The region where the second connection electrode DJ2 is located overlaps with the orthographic projection of the second end of the fourth wiring L4 on the dielectric substrate 1. The first connection electrode DJ1 and the second connection electrode DJ2 in the same connection electrode group flow in opposite directions.

It should be noted that in this specification, the first end and the second end of each of the wirings are named according to the flow directions of the currents. The current flows from the first end to the second end of the wiring, as exemplified by the flow directions of the currents marked in FIG. 3. The first ends and the second ends of the first wiring L1, the second wiring L2, the third wiring L3, the fourth wiring L4 and the fifth wiring L5 are all named according to this rule and will not be described in detail later.

In an exemplary embodiment, as shown in FIG. 3, the orthographic projections of the first connection electrode DJ1 and the second connection electrode DJ2 in the same connection electrode group on the film layer where the fifth wiring L5 is located fall within the region where the same fifth wiring L5 is located.

It should be noted that in the present description, the first connection electrode DJ1 and the second connection electrode DJ2 may be determined according to the projected positions of the first end and the second end of the fourth wiring L4 relative to two connection electrodes DJ in the same connection electrode group. Here, the connection electrode overlapping with the projection of the first end of the fourth wiring L4 is a first connection electrode DJ1. The connection electrode overlapping with the projection of the second end of the fourth wiring L4 is a second connection electrode DJ2. The first end and the second end of the fourth wiring L4 are related to the flow direction of the current in the fourth wiring L4. When the flow directions of the currents in the fourth wiring L4 are opposite, the first connection electrode DJ1 and the second connection electrode DJ2 exchange positions.

In at least one embodiment provided by the present disclosure, as shown in connection with FIG. 1 or FIG. 3, the inductance structure further includes N fourth wirings L4 disposed in the same row and N+1 fifth wirings L5 disposed in the same row. The orthographic projections of the N^{th} one of the fourth wirings L4 and the (N+1)^{th} one of the fifth wirings L5 on the dielectric substrate 1 overlap and the flow directions of the currents are the same.

Exemplarily, the number of the fifth wirings L5 is one greater than the number of the fourth wirings L4.

Exemplarily, the orthographic projections of the first one of the fourth wirings L4 and the second one of the fifth wirings L5 on the dielectric substrate 1 overlap, and the flow directions of the currents are the same. The orthographic projections of the second one of the fourth wirings L4 and the third one of the fifth wirings L5 on the dielectric substrate 1 overlap, and the flow directions of the currents are the same. The orthographic projections of the third one of the fourth wirings L4 and the fourth one of the fifth wirings L5 on the dielectric substrate 1 overlap and the flow directions of the currents are the same.

In the embodiment of the present disclosure, as shown in FIG. 3, the fourth wirings L4 are referred to as a first one of the fourth wirings L4, a second one of the fourth wirings L4, a third one of the fourth wirings L4, etc. respectively, from the left side of the inductance structure. For other orders, for example, the first wiring L1, the second wiring L2, the fifth wiring L5 are also ordered from the left side of the inductance structure.

In at least one embodiment provided in the present disclosure, as shown in conjunction with FIG. 1 or FIG. 3, on the first surface B1, the second end (the second end is located in the direction pointed by the arrow) of the first one of the first wirings L1 and the second end (the second end is located in the direction pointed by the arrow) of the first one of the second wirings L2 are electrically connected to the first end (the first end is located in the direction facing away from the arrow) of the first one of the fourth wirings L4, respectively. A first end (the first end is located in the direction facing away from the arrow) of the second one of the first wirings L1 and a first end (the first end is located in the direction facing away from the arrow) of the second one of the second wirings L2 are electrically connected to a second end (the second end is located in the direction pointed by the arrow) of the first one of the fourth wirings L4 direction pointed, respectively.

The second end of the N^{th} one of the first wirings L1 and the second end of the N^{th} one of the second wirings L2 are electrically connected to the first end of the N^{th} one of the fourth wirings L4, respectively. The first end of the (N+1)^{th} one of the first wirings L1 and the first end of the (N+1)^{th} one of the second wirings L2 are electrically connected to the second end of the N^{th} one of the fourth wirings L4, respectively.

Exemplarily, when N=2, the second end of the second one of the first wirings L1 and the second end of the second one of the second wirings L2 are electrically connected to the first end of the second one of the fourth wirings L4, respectively. The first end of the third one of the first wirings L1 and the first end of the third one of the second wirings L2 are electrically connected to the second end of the second one of the fourth wirings L4, respectively.

Exemplarily, when N=3, the second end of the third one of the first wirings L1 and the second end of the third one of the second wirings L2 are electrically connected to the first end of the third one of the fourth wirings L4, respectively. The first end of the fourth one of the first wirings L1 and the first end of the fourth one of the second wirings L2 are electrically connected to the second end of the third one of the fourth wiring L4, respectively.

Exemplarily, when N=5, the second end of the fifth one of the first wirings L1 and the second end of the fifth one of the second wirings L2 are electrically connected to the first end of the fifth one of the fourth wirings L4, respectively. The first end of the sixth one of the first wirings L1 and the first end of the sixth one of the second wirings L2 are electrically connected to the second end of the fifth one of the fourth wirings L4, respectively.

Exemplarily, when N=6, the second end of the sixth one of the first wirings L1 and the second end of the sixth one of the second wirings L2 are electrically connected to the first end of the sixth one of the fourth wiring L4, respectively. The first end of the seventh one of the first wiring L1 and the first end of the seventh one of the second wiring L2 are electrically connected to the second end of the sixth one of the fourth wiring L4, respectively.

In at least one embodiment provided in the present disclosure, in conjunction with FIG. 1 or FIG. 3, the inductance structure includes N+1 connection electrode groups disposed in the same row. A first end (the first end is located in the direction facing away from the arrow) of the third wiring L3 is electrically connected to an (N+1)^{th} one of the second connection electrodes DJ2. A second end (the first end is located in the direction pointed by the arrow) of the third wiring L3 is electrically connected to a first end (the first end is located in the direction facing away from the arrow) of the first one of the first wirings L1 and a first end (the first end is located in the direction facing away from the arrow) of the first one of the second wirings L2, respectively. A first end of the first one of the first wirings L1 and a first end of the first one of the second wirings L2 are electrically connected to the first one of the second connection electrodes DJ2, respectively. A first end of the first one of the first wirings L1 and a first end of the first one of the second wirings L2 are electrically connected to the second one of the first connection electrodes DJ1, respectively. A first end of the N^{th} one of the first wirings L1 and a first end of the N^{th} one of the second wirings L2 are electrically connected to the N^{th} one of the second connection electrodes DJ2, respectively. A second end of the N^{th} one of the first wirings L1 and a second end of the N^{th} one of the second wirings L2 are electrically connected to the (N+1)^{th} one of the first connection electrodes DJ1, respectively.

Exemplarily, when N=2, a first end of the second one of the first wirings L1 and a first end of the second one of the second wirings L2 are electrically connected to the second one of the second connection electrodes DJ2, respectively. A second end of the second one of the first wirings L1 and a second end of the second one of the second wirings L2 are electrically connected to a third one of the first connection electrodes DJ1, respectively.

Exemplarily, when N=3, a first end of the third one of the first wirings L1 and a first end of the third one of the second wirings L2 are electrically connected to a third one of the second connection electrodes DJ2, respectively. A second end of the third one of the first wirings L1 and a second end of the third one of the second wirings L2 are electrically connected to a fourth one of the first connection electrodes DJ1, respectively.

Exemplarily, when N=5, a first end of a fifth one of the first wirings L1 and a first end of the fifth one of the second wirings L2 are respectively electrically connected to the fifth one of the second connection electrodes DJ2. A second end of the fifth one of the first wirings L1 and a second end of the fifth one of the second wirings L2 are electrically connected to the sixth one of the first connection electrodes DJ1, respectively.

In at least one embodiment provided by the present disclosure, as shown in FIGS. 1-3, 5-6, the orthographic projection of the region of the third wiring L3 except the regions of the first end and the second end thereof on the dielectric substrate 1 does not overlap with the region where the connection electrode group is located.

Exemplarily, the region of the third wiring L3 except the regions of the first end and the second end thereof may be referred to as a main part of the third wiring L3.

In some examples, the orthographic projection of the main part of the third wiring L3 on the dielectric substrate 1 does not overlap with the orthographic projections of the first wiring L1, the second wiring L2, the fourth wiring L4 and the fifth wiring L5 on the dielectric substrate 1.

In the embodiments of the present disclosure, by arranging that the orthographic projection of the main part of the third wiring L3 on the dielectric substrate 1 does not overlap with the orthographic projection of the first wiring L1, the second wiring L2, the fourth wiring L4 and the fifth wiring L5 on the dielectric substrate 1, the interference of the mutual inductance between the first wiring L1 and the second wiring L2 by the current in the third wiring L3 may be greatly reduced, and the interference of the mutual inductance between the fourth wiring L4 and the fifth wiring L5 may be reduced, so as to maximize the mutual inductance in the inductance structure, further increase the inductance value of the inductance structure and improve the performance of the inductance structure. The application flexibility of the inductance structure is improved and the application field of the inductance structure is expanded on the condition that the size of inductance structure is basically unchanged.

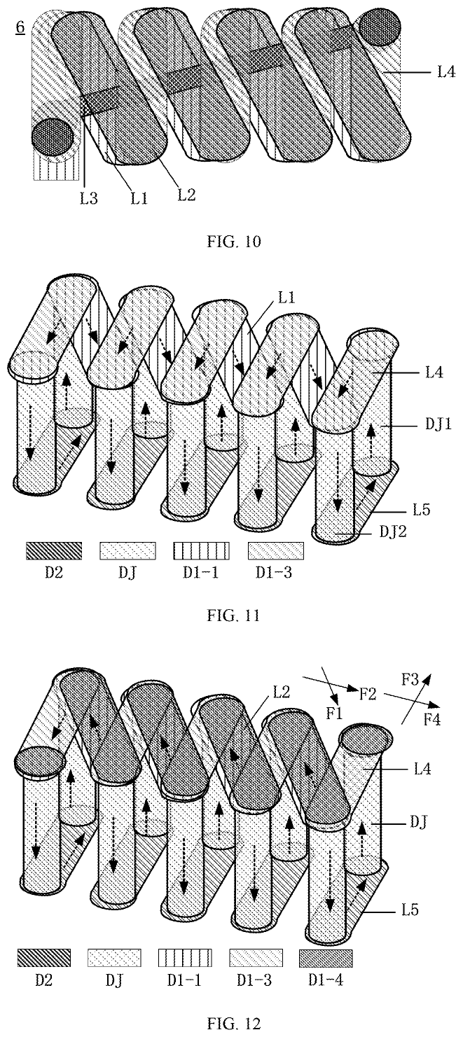

In at least one embodiment of the present disclosure, as shown in FIGS. 7-9, the inductance structure includes N first wirings L1 disposed in the same row and N second wirings L2 disposed in the same row, where N is a positive integer, and N is greater than or equal to 1. As shown in FIG. 10, the orthographic projection of the N^{th} one of the first wirings L1 and the N^{th} one of the second wirings L2 on the dielectric substrate 1 overlap, and the flow directions of the currents are the same. Here, the direction pointed by a dotted arrow in FIGS. 7 and 8 may be a flow direction of the current, and FIG. 9 is a right side view of FIG. 8.

It should be noted that, in order to clearly embody the positional relationship of the orthographic projections of the N^{th} one of the first wirings L1 and the N^{th} one of the second wirings L2 on the dielectric substrate 1, in FIG. 10, the orthographic projections of the N^{th} one of the first wirings L1 and the N^{th} one of the second wirings L2 on the dielectric substrate 1 partial overlap and are drawn as an example. In some embodiments, the orthographic projections of the N^{th} one of the first wirings L1 and the N^{th} one of the second wirings L2 on the dielectric substrate 1 may completely overlap.

In an exemplary embodiment, as shown in FIGS. 7 and 8, two connection electrodes DJ are divided into one group, and the same connection electrode group is in contact with and connected to the same fifth wiring L5. The same connection electrode group includes a first connection electrode DJ1 and a second connection electrode DJ2. The region where the first connection electrode DJ1 is located overlaps with the orthographic projection of the first end of the fourth wiring L4 on the dielectric substrate 1. The region where the second connection electrode DJ2 is located overlaps with the orthographic projection of the second end of the fourth wiring L4 on the dielectric substrate 1. The currents of the first connection electrode DJ1 and the second connection electrode DJ2 in the same connection electrode group flow in opposite directions.

In at least one embodiment provided by the present disclosure, as shown in FIGS. 7 and 8, the inductance structure further includes N+1 fourth wirings L4 disposed in the same row and N+1 fifth wirings L5 disposed in the same row. The orthographic projections of the N^{th} one of the fourth wirings L4 and the N^{th} one of the fifth wirings L5 on the dielectric substrate 1 overlap and the flow directions of the currents are the same.

In at least one embodiment provided in the present disclosure, as shown in conjunction with FIGS. 7 and 8, on the first surface B1, the second end (the second end is located in the direction facing away from the arrow) of the first one of the fourth wirings L4 is respectively electrically connected to the first end (the first end is located in the direction pointed by the arrow) of the first one of the first wirings L1 and the first end (the first end is located in the direction pointed by the arrow) of the first one of the second wirings L2. The first end of the (N+1)^{th} one of the fourth wirings L4 is electrically connected to the second end of the N^{th} one of the first wirings L1 and the second end of the N^{th} one of the second wirings L2, respectively. A second end of the (N+1)^{th} one of the fourth wirings L4 is electrically connected to a first end of the (N+1)^{th} one of the first wirings L1 and a first end of the (N+1)^{th} one of the second wirings L2, respectively.

Exemplarily, when N=3, a first end of the fourth one of the fourth wirings L4 is electrically connected to a second end of the third one of the first wirings L1 and a second end of the third one of the second wirings L2, respectively. A second end of the fourth one of the fourth wirings L4 is electrically connected to a first end of the fourth one of the first wirings L1 and a first end of the fourth one of the second wirings L2, respectively.

Exemplarily, when N=4, a first end of the fifth one of the fourth wirings L4 is electrically connected to a second end of the fourth one of the first wirings L1 and a second end of the fourth one of the second wirings L2, respectively. A second end of the fifth one of the fourth wirings L4 is electrically connected to a first end of the fifth one of the first wirings L1 and a first end of the fifth one of the second wiring L2, respectively.

Exemplarily, when N=5, a first end of the sixth one of the fourth wirings L4 is electrically connected to a second end of the fifth one of the first wirings L1 and a second end of the fifth one of the second wirings L2, respectively. A second end of the sixth one of the fourth wirings L4 is electrically connected to a first end of the sixth one of the first wirings L1 and a first end of the sixth one of the second wirings L2, respectively.

In at least one embodiment provided by the present disclosure, and as shown in conjunction with FIGS. 7 and 8, the inductance structure includes N+1 connection electrode groups disposed in the same row. A first end of a third wiring L3 is electrically connected to an (N+1)^{th} one of the second connection electrodes DJ2. A second end of the third wiring L3 is electrically connected to a first end of a first one of the fourth wirings L4.

In at least one embodiment provided by the present disclosure, as shown in connection with FIGS. 7 and 8, the orthographic projections of each first wiring L1, each second wiring L2, each fourth wiring L4 and each fifth wiring L5 on the dielectric substrate 1 overlap with the orthographic projection of the third wiring L3 on the dielectric substrate 1, respectively.

Herein, the orthographic projection of the third wiring L3 on the dielectric substrate 1 overlaps with the orthographic projections of each first wiring L1, each second wiring L2, each fourth wiring L4 and each fifth wiring L5 on the dielectric substrate 1, respectively.

In addition, as shown in FIGS. 7, 8 and 10, the extension direction of the orthographic projection of the third wiring L3 on the dielectric substrate 1 respectively intersects with the extension direction of the orthographic projections of each first wiring L1, each second wiring L2, each fourth wiring L4 and each fifth wiring L5 on the dielectric substrate 1.

In at least one embodiment provided in the present disclosure, as shown in conjunction with FIGS. 11, 12 and 14, the first conductive structure 6 includes a first one of the first conductive sub-layers D1-1, a third one of the first conductive sub-layer D1-3 and a fourth one of the first conductive sub-layers D1-4 which are successively disposed in a direction away from the dielectric substrate 1. FIG. 14 is a right side view of FIG. 12.

As shown in conjunction with FIGS. 12 and 14, a first one of the first conductive sub-layers D1-1 includes a plurality of first wirings L1 extending along a first direction F1 and arranged along a second direction F2. A fourth one of the first conductive sub-layers D1-4 includes a plurality of second wirings L2 extending along the first direction F1 and arranged along the second direction F2. The first direction F1 and the second direction F2 intersect. The orthographic projections of the first wiring L1 and the second wiring L2 on the dielectric substrate 1 at least partially overlap.

The third one of the first conductive sub-layers D1-3 includes a plurality of fourth wirings L4 extending along a third direction F3 and arranged along a fourth direction F4. The second conductive sub-layer D2 includes a plurality of fifth wirings L5 extending along the third direction F3 and arranged along the fourth direction F4. The third direction F3 and the fourth direction F4 intersect. The orthographic projections of the fourth wirings L4 and the fifth wirings L5 on the dielectric substrate 1 at least partially overlap. The first direction F1 and the third direction F3 intersect.

In some examples, the second direction F2 may be roughly parallel to the fourth direction F4.

The materials of the first one of the first conductive sub-layers D1-1, the third one of the first conductive sub-layers D1-3 and the fourth one of the first conductive sub-layers D1-4 may be described with reference to the foregoing description and will not be described in detail herein.

There is no limitation on whether the lengths and widths (also referred to as line widths, Width) of the first wiring L1, the second wiring L2, the fourth wiring L4 and the fifth wiring are the same.

In some embodiments, the first wiring L1 and the second wiring L2 have the same length.

In some embodiments, the fourth wiring L4 and the fifth wiring L5 have the same length.

In some examples, the line widths of the first wiring L1 and the second wiring L2 are the same.

In some examples, the line widths of the fourth wiring L4 and the fifth wiring L5 are the same.

There is no limitation on whether the thicknesses of the first wiring L1, the second wiring L2, the third wiring L3, the fourth wiring L4, and the fifth wiring L5 are the same.

In some examples, at least some of the first wiring L1, the second wiring L2, the third wiring L3, the fourth wiring L4, and the fifth wiring L5 have approximately the same thickness.

In some examples, at least some of the first wiring L1, the second wiring L2, the third wiring L3, the fourth wiring L4, and the fifth wiring L5 may include straight lines. Alternatively, at least some of the first wiring L1, the second wiring L2, the third wiring L3, the fourth wiring L4, and the fifth wiring L5 may include arcs. Alternatively, at least some of the first wiring L1, the second wiring L2, the third wiring L3, the fourth wiring L4, and the fifth wiring L5 may include a broken line segment formed by straight line segments. Alternatively, at least some of the first wiring L1, the second wiring L2, the third wiring L3, the fourth wiring L4, and the fifth wiring L5 may include a combination of the straight lines and the arcs.

In at least one embodiment provided by the present disclosure, as shown in connection with FIGS. 11, 12 and 14, the inductance structure includes N first wirings L1 disposed in the same row, N second wirings L2 disposed in the same row, N+1 fourth wirings L4 disposed in the same row, and N+1 fifth wirings L5 disposed in the same row, where N is a positive integer, and N is greater than or equal to 1.

With reference to the direction of an arrow marked in FIGS. 11 and 12 (the direction of the arrow indicates the flow direction of the current), the orthographic projections of the N^{th} one of the first wirings L1 and the N^{th} one of the second wirings L2 on the dielectric substrate 1 overlap, and the flow direction of the current is opposite. The orthographic projection of the N^{th} one of the fourth wirings L4 and the N^{th} one of the fifth wirings L5 on the dielectric substrate 1 overlap, and the flow directions of the currents are opposite.

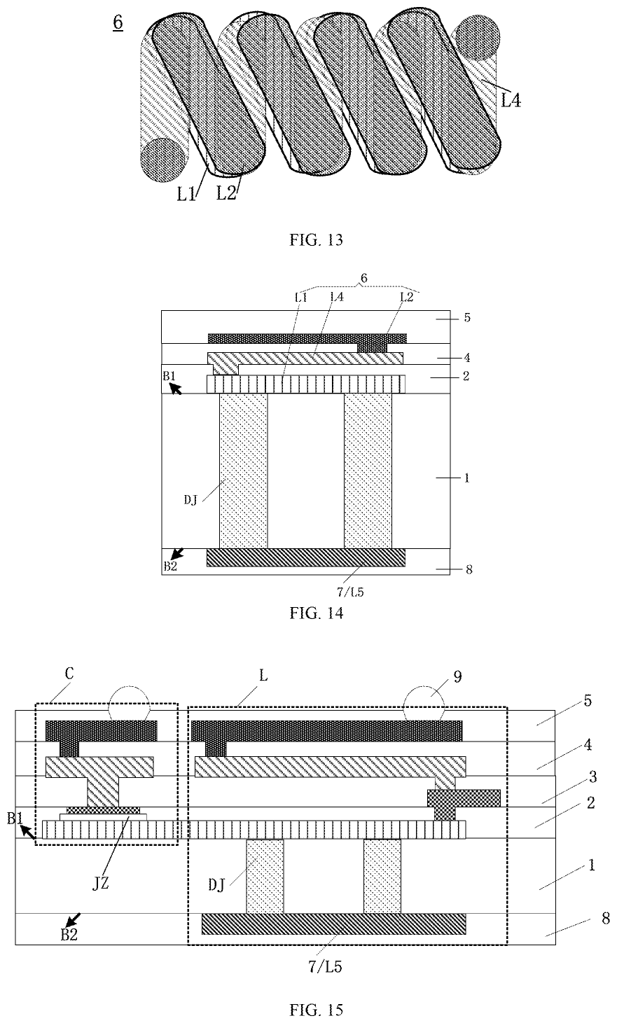

It should be noted that, in order to clearly embody the positional relationship of the orthographic projections of the N^{th} one of the first wirings L1 and the N^{th} one of the second wirings L2 on the dielectric substrate 1, in FIG. 13, the orthographic projections of the N^{th} one of the first wirings L1 and the N^{th} one of the second wirings L2 on the dielectric substrate 1 partial overlap and are drawn as an example. In some embodiments, the orthographic projection of the N^{th} one of the first wirings L1 and the N^{th} one of the second wirings L2 on the dielectric substrate 1 may completely overlap.

Two connection electrodes are divided into one group, and the same connection electrode group is in contact with and connected to the same fifth wiring L5. The same connection electrode group includes a first connection electrode DJ1 and a second connection electrode DJ2. The region where the first connection electrode DJ1 is located overlaps with the orthographic projection of the first end of the fourth wiring L4 on the dielectric substrate 1. The region where the second connection electrode DJ2 is located overlaps with the orthographic projection of the second end of the fourth wiring L4 on the dielectric substrate 1. The currents of the first connection electrode DJ1 and the second connection electrode DJ2 in the same connection electrode group flow in opposite directions.

It should be noted that in this specification, the first end and the second end of each wiring are named according to the flow direction of the current from the first end to the second end of the wiring. At this time, the inductance structure shown in FIG. 12 is different from the inductance structure shown in FIG. 3 or FIG. 8 in that the positions of the first end of the fourth wiring L4 are changed due to a change in the flow direction of the current, so that the positions of the first connection electrode DJ1 and the second connection electrode DJ2 in the inductance structure shown in FIG. 12 are exchanged compared with the inductance structure shown in FIG. 3 or FIG. 8.

In an exemplary embodiment, as shown in FIG. 12, the orthographic projections of the first connection electrode DJ1 and the second connection electrode DJ2 in the same connection electrode group on the film layer where the fifth wiring L5 is located fall within the region where the same fifth wiring L5 is located.

In at least one embodiment provided in the present disclosure, as shown in conjunction with FIGS. 11 and 12, a first one of the first connection electrodes DJ1 is respectively electrically connected to a first end (at the direction facing away from the arrow) of a first one of the fourth wirings L4 and a first end (at the direction facing away from the arrow) of the first one of the first wirings L1. A second end (at the direction pointed by the arrow) of the first one of the fourth wirings L4 is electrically connected to a first one of the second connection electrodes DJ2. A second end of the first one of the first wirings L2 is electrically connected to a second one of the second connection electrodes DJ2 and a first end of a first one of the second wirings L2, respectively. The second end of the first one of the second wirings L2 is electrically connected to the first end of the first one of the first wirings L1 and the first end of the first one of the fourth wirings L4, respectively.

The N^{th} one of the first connection electrodes DJ1 is electrically connected to the first end of the N^{th} one of the fourth wirings L4 and the first end of the N^{th} one of the first wirings L1, respectively. The second end of the N^{th} one of the fourth wirings L4 is electrically connected to the N^{th} one of the second connection electrodes DJ2. The second end of the No one of the first wirings L1 is electrically connected to the (N+1)^{th} one of the second connection electrode DJ2 and the first end of the N^{th} one of the second wirings L2 respectively. The second end of the N^{th} one of the second wirings L2 is electrically connected to the first end of the N^{th} one of the first wirings L1 and the first end of the N^{th} one of the fourth wirings L4, respectively.

For example, when N=4, a fourth one of the first connection electrodes DJ1 is electrically connected to a first end of a fourth one of the fourth wirings L4 and a first end of a fourth one of the first wiring L1, respectively. A second end of the fourth one of the fourth wirings L4 is electrically connected to a fourth one of the second connection electrodes DJ2. A second end of the fourth one of the first wirings L1 is electrically connected to a fifth one of the second connection electrodes DJ2 and a first end of a fourth one of the second wiring L2, respectively. A second end of the fourth one of the second wirings L2 is electrically connected to the first end of the fourth one of the first wirings L1 and the first end of the fourth one of the fourth wirings L4, respectively.

For example, when N=5, a fifth one of the first connection electrodes DJ1 is electrically connected to a first end of a fifth one of the fourth wirings L4 and a first end of the fifth one of the first wirings L1 respectively. A second end of the fifth one of the fourth wirings L4 is electrically connected to a fifth one of the second connection electrodes DJ2. A second end of the fifth one of the first wirings L1 is electrically connected to a sixth one of the second connection electrodes DJ2 and a first end of the fifth one of the second wirings L2 respectively. A second end of the fifth one of the second wirings L2 is electrically connected to the first end of the fifth one of the first wirings L1 and the first end of the fifth one of the fourth wirings L4, respectively.

For example, when N=6, a sixth one of the first connection electrodes DJ1 is electrically connected to a first end of a sixth one of the fourth wirings L4 and a first end of a sixth one of the first wirings L1, respectively. A second end of the sixth one of the fourth wirings L4 is electrically connected to a sixth one of the second connection electrodes DJ2. A second end of the sixth one of the first wiring L1 is electrically connected to a seventh one of the second connection electrodes DJ2 and a first end of the sixth one of the second wirings L2 respectively. A second end of the sixth one of the second wirings L2 is electrically connected to the first end of the sixth one of the first wirings L1 and the first end of the sixth one of the fourth wirings L4, respectively.

In at least one embodiment provided by the present disclosure, as shown in FIGS. 4 and 9, the inductance structure further includes a first insulating layer 2, a second insulating layer 3, a third insulating layer 4, a first protective layer 5 and a second protective layer 8. The first insulating layer 2 is located between the first one of the first conductive sub-layers D1-1 and the second one of the first conductive sub-layers D1-2. The second insulating layer 3 is located between the second one of the first conductive sub-layers D1-2 and the third one of the first conductive sub-layers D1-3. The third insulating layer 4 is located between the third one of the first conductive sub-layers D1-3 and the fourth one of the first conductive sub-layers D1-4. The first protective layer 5 covers the fourth one of the first conductive sub-layers D1-4, and the second protective layer 8 covers the second one of the conductive sub-layers D2.

In at least one embodiment provided in the present disclosure, as shown in FIG. 14, the inductance structure further includes a first insulating layer 2, a third insulating layer 4, a first protective layer 5 and a second protective layer 8. The first insulating layer 2 is located between the first one of the first conductive sub-layers D1-1 and the third one of the first conductive sub-layers D1-3. The third insulating layer 4 is located between the third one of the first conductive sub-layers D1-3 and the fourth one of the first conductive sub-layers D1-4. The first protective layer 5 covers the fourth one of the first conductive sub-layers D1-4, and the second protective layer 8 covers the second one of the conductive sub-layers D2.

The materials of the above-mentioned first insulating layer 2, second insulating layer 3, third insulating layer 4, first protective layer 5 and second protective layer 8 are all insulating materials. The insulating material may include, among others, an organic insulating material or an inorganic insulating material.

Exemplarily, the organic insulating material may include photoresist, resin, e.g. epoxy, polyimide, acryl resin, etc.

Exemplarily, the inorganic insulating material may include at least one of silicon nitride, silicon oxide, and silicon oxynitride.

In the embodiments of the present disclosure, the above-mentioned materials of the first insulating layer 2, the second insulating layer 3, the third insulating layer 4, the first protective layer 5 and the second protective layer 8 all take organic materials as an example.

In at least one embodiment provided by the present disclosure, the thickness of each of the first conductive sub-layer D1 and the second conductive sub-layer D2 ranges from 1 μm to 10 μm.

Exemplarily, the first conductive sub-layer D1 and the second conductive sub-layer D2 each have a thickness ranging from 1.5 μm to 7 μm. For example, the thickness may be 1.5 μm, 2 μm, 4 μm, 6.5 μm or 7 μm.

There is no limitation on whether the thicknesses of the first conductive sub-layer D1 and the second conductive sub-layer D2 are the same as described above. For example, the thickness can be set according to the material and conductivity requirements of the wirings provided in the first conductive sub-layer D1 and the second conductive sub-layer D2.

In practical applications, when the materials of the first conductive sub-layer D1 and the second conductive sub-layer D2 both meet the requirements of their electrical conductivity, the thicknesses of the first conductive sub-layer D1 and the second conductive sub-layer D2 may be set to be approximately the same, so as to simplify the preparation process and reduce the difficulty of the preparation process.

In some examples, since the thickness of each of the first conductive sub-layer D1 and the second conductive sub-layer D2 ranges from 1 μm to 10 μm, and the thickness is relatively thick. In order to improve the stability between two adjacent conductive film layers, the thickness of at least part of the insulating layer may be set to be greater than the thickness of the conductive sub-layer.

For example, the thickness of the first insulating layer 2 is greater than or equal to the thickness of the first one of the first conductive sub-layers D1-1.

For example, the thickness of the second insulating layer 3 is greater than or equal to the thickness of the second one of the first conductive sub-layers D1-2.

For example, the thickness of the third insulating layer 4 is greater than or equal to the thickness of the third one of the first conductive sub-layers D1-3.

For example, the thickness of the first protective layer 5 is greater than or equal to the thickness of the fourth one of the first conductive sub-layers D1-4.

For example, the thickness of the second protective layer 8 is greater than or equal to the thickness of the second conductive sub-layer D2.

In at least one embodiment provided herein, the connection electrode DJ includes a metallic material.

Alternatively, the connection electrode DJ includes a resin and a metal material wrapping the resin.

It should be noted that when the conductive material is filled in the connection through-holes using the electroplating process, the conductive material is preferentially deposited on side walls of the connection through-hole, and there may be a case where the conductive material is not completely filled in the center of the connection through-holes and a gap occurs. At this time, the gap is filled with a resin material so as to improve the mechanical strength of the connection electrode DJ and improve the support effect for the other film layers. When the connection electrode DJ includes a resin and a metal material wrapping the resin, the plane pattern of the conductive region of a side of the connection electrode DJ close to the first surface B1 and/or the second surface B2 may be a ring shape, such as a circular ring or a polygonal ring shape.

In at least one embodiment provided herein, at least one of the first wiring L1, the second wiring L2, the fourth wiring L4 and the fifth wiring L5 includes a plurality of sub-wirings disposed in parallel, with a gap between two adjacent sub-wirings, and each sub-wiring having roughly the same line width.

In the embodiments of the present disclosure, by providing that at least one of the first wiring L1, the second wiring L2, the fourth wiring L4 and the fifth wiring L5 includes a plurality of sub-wirings disposed in parallel, with a gap between two adjacent sub-wirings, so that mutual inductance can be generated between the respective sub-wirings of the first wiring L1, the second wiring L2, the fourth wiring L4 and the fifth wiring L5 thereby further improving the inductance density and inductance value of the inductance structure with the size of the inductance structure being constant.

In at least one embodiment provided by the present disclosure, the angle between the first direction F1 and the third direction F3 is an acute angle, so that the space in which the wirings are arranged may be reduced as much as possible, thereby reducing the spatial size of the inductance structure.

In at least one embodiment provided by the present disclosure, the third wiring L3 includes a plurality of sub-wirings disposed in parallel, with a gap between two adjacent sub-wirings, and the line width of each sub-wiring is approximately the same, so that mutual inductance can be generated between the sub-wirings, thereby further increasing the inductance density and the inductance value of the inductance structure with the size of the inductance structure being constant.

In at least one embodiment provided by the present disclosure, the line width of the third wiring L3 is less than the line widths of the first wiring L1, the second wiring L2 and the fourth wiring L4, so that the interference of the current in the third wiring L3 on the mutual inductance between the first wiring L1 and the second wiring L2 and the mutual inductance between the fourth wiring L4 and the fifth wiring L5 can be reduced to a large extent, thereby further increasing the inductance density and the inductance value of the inductance structure with the size of the inductance structure being fixed.

Embodiments of the present disclosure provide a filter, as shown in FIG. 15, including at least one inductance structure L as described hereinbefore and at least one capacitor C. Here, the insulating medium in the capacitor C is labeled JZ. In addition, the filter further includes solder balls or conductive posts 9 for electrically connecting the filter with other components in the radio frequency module.

Embodiments of the present disclosure provide a filter including a 3D inductance structure. By providing the inductance structure, on the one hand, one of the first conductive structure 6 and the second conductive structure 7 provided in the inductance structure includes a plurality of sub-layers, and the other includes at least one sub-layer. It increases the number of conductive layers constituting the wire (coil), thereby extending the effective length of the coil forming the inductance structure, thereby increasing the inductance density of the inductance structure and increasing the inductance value. On the other hand, the orthographic projections of two sub-layers in the first conductive structure 6 and the second conductive structure 7 in the inductance structure on the dielectric substrate 1 at least partially overlap. When the flow directions of the currents of the both are the same, the mutual inductance of the inductance structure may be effectively increased, the inductance value of the inductance structure is further increased, and the performance of the inductance structure is improved. The application flexibility of the inductance structure is improved and the application field of the inductance structure is expanded on the condition that the size of inductance structure is basically unchanged.

Embodiments of the present disclosure provide a package substrate including at least one inductance structure L as described hereinbefore.

A package substrate provided in an embodiment of the present disclosure includes a 3D inductance structure, and by providing the inductance structure, on the one hand, one of the first conductive structure 6 and the second conductive structure 7 provided in the inductance structure includes at least three sub-layers, and the other includes at least one sub-layer (for example, as shown in conjunction with FIGS. 1 and 4, the first conductive structure 6 includes a sub-layer D1-1, a sub-layer D1-2, a sub-layer D1-3 and a sub-layer D1-4. The second conductive structure 7 includes a sub-layer D2), which increases the number of conductive layers constituting the wire (coil), thereby extending the effective length of the coil forming the inductance structure, thereby increasing the inductance density of the inductance structure and increasing the inductance value. On the other hand, the orthographic projections of two sub-layers in the first conductive structure 6 and the second conductive structure 7 in the inductance structure on the dielectric substrate 1 at least partially overlap. When the flow directions of the currents of the both are the same, the mutual inductance of the inductance structure may be effectively increased, the inductance value of the inductance structure is further increased, and the performance of the inductance structure is improved. The application flexibility of the inductance structure is improved and the application field of the inductance structure is expanded on the condition that the size of inductance structure is basically unchanged.

Embodiments of the present disclosure provide a method for preparing an inductance structure, and the method is specifically described as follows:

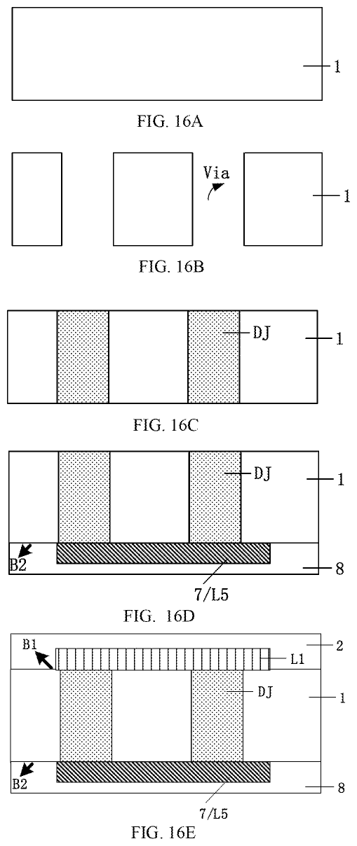

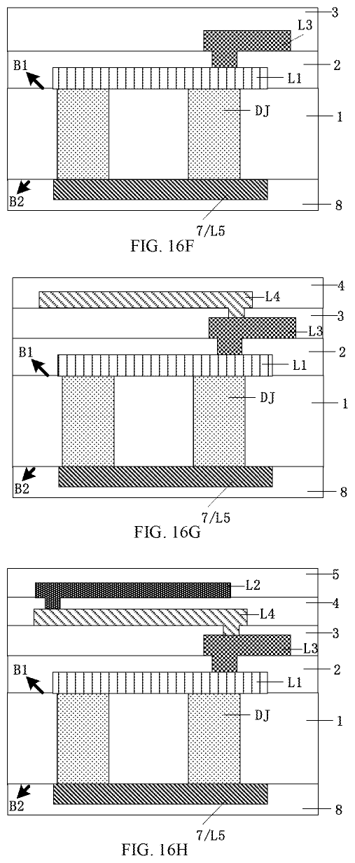

S01, a substrate (a dielectric substrate 1) as shown in FIG. 16A is selected, and a through-hole (a connection through-hole Via) is fabricated at a reserved hole site of the substrate to obtain a structure as shown in FIG. 16B.

Exemplarily, the dielectric substrate 1 has a thickness of 0.2 mm to 0.5 mm.

Exemplarily, the dielectric substrate 1 may be a glass substrate, a silicon-based substrate, a ceramic substrate, or the like.

As an example, the hole diameter of the connection through-hole Via may be in the range of 30-100 μm, and the cross-sectional shape of the hole may be columnar or hourglass-shaped depending on the through-hole technology.

S02, the metallization filling is performed in the connection through-holes, resulting in a connection electrode DJ as shown in FIG. 16C.

In some embodiments, the metal communication within the through-holes may be by electroplating techniques to inject copper metal into the through-holes to effect conduction of the circuit within the through-holes. It should be noted that when the conductive material is filled in the connection through-holes using the electroplating process, the conductive material is preferentially deposited on side walls of the connection through-holes, and there may be a case where the conductive material is not completely filled in the center of the connection through-holes and a gap occurs. At this time, the gap is filled with a resin material so as to improve the mechanical strength of the connection electrode DJ and support the other film layers.

S03, the preparation of the conductive structure is performed on the second surface B2 of the dielectric substrate 1 to obtain a second conductive structure 7 as shown in FIG. 16D. The second conductive structure 7 includes a fifth wiring L5.

S04, a second protective layer 8 as shown in FIG. 16D is formed, and the second protective layer 8 covers the second conductive structure 7.

Exemplarily, the thickness of the second protective layer 8 is greater than or equal to 2 μm.

S05, a first one of the first conductive sub-layers D1-1 (including a first wiring L1) as shown in FIG. 16E, a first insulating layer 2, a second one of the first conductive sub-layers D1-2 (including a third wiring L3) as shown in FIG. 16F, a second insulating layer 3, a third one of the first conductive sub-layers D1-3 (including a fourth wiring L4) as shown in FIG. 16G, a third insulating layer 4, a fourth one of the first conductive sub-layers D1-4 (including a second wiring L2) as shown in FIG. 16H and a first protective layer 5 are successively formed on the first surface B1.

Herein, the first one of the first conductive sub-layers D1-1 (including a first wiring L1), the second one of the first conductive sub-layers D1-2 (including a third wiring L3), the third one of the first conductive sub-layers D1-3 (including a fourth wiring L4) and the fourth one of the first conductive sub-layers D1-4 (including a second wiring L2) can all be prepared by the electroplating process. Specifically, each patterned first conductive sub-layer D1 can be formed by processes of electroplating film-forming, photoresist coating, exposure and etching.

It should be noted that only the preparation process of the structure related to the invention point is introduced here. The specific components and materials of the inductor structure can refer to the previous explanation, and will not be repeated here.

The above is only a specific implementation of the present disclosure, but the scope of protection of the present disclosure is not limited to this. Any person skilled in the art within the scope of the disclosed technology by the present disclosure can easily think of changes or replacements, which should be covered within the scope of protection of the present disclosure. Therefore, the scope of protection of the present disclosure shall be based on the scope of protection of the claims.

1. An inductance structure, comprising:
a dielectric substrate, wherein the dielectric substrate is provided with a plurality of connection through-holes penetrating in a thickness direction of the dielectric substrate, connection electrodes are provided in the connection through-holes, and the dielectric substrate further comprises a first surface and a second surface oppositely disposed in the thickness direction of the dielectric substrate;
a first conductive structure disposed on the first surface; and
a second conductive structure disposed on the second surface;
wherein the first conductive structure and the second conductive structure are electrically connected by the connection electrodes to form a coil of the inductance structure; one of the first conductive structure and the second conductive structure comprises at least three sub-layers, and the other comprises at least one sub-layer; and orthographic projections of two of the sub-layers of the first conductive structure and the second conductive structure on the dielectric substrate at least partially overlap, and flow directions of currents of the two of the sub-layers are roughly parallel.

2. The inductance structure according to claim 1, wherein the sub-layer in the first conductive structure is a first conductive sub-layer and the sub-layer in the second conductive structure is a second conductive sub-layer;
wherein the first conductive structure comprises at least three first conductive sub-layers and the second conductive structure comprises at least three second conductive sub-layers; or
the first conductive structure comprises the at least three first conductive sub-layers and the second conductive structure comprises one of the second conductive sub-layers.

3. The inductance structure according to claim 2, wherein the orthographic projections of at least two of the first conductive sub-layers on the dielectric substrate at least partially overlaps, and the flow directions of the currents of both are parallel.

4. The inductance structure according to claim 2, wherein the orthographic projection of at least one of the first conductive sub-layers on the dielectric substrate and the orthographic projection of the second conductive sub-layer on the dielectric substrate at least partially overlap, and the flow directions of the currents of both are parallel.

5. The inductance structure according to claim 2, wherein when the first conductive structure comprises the at least three first conductive sub-layers and the second conductive structure comprises one of the second conductive sub-layers,
the first conductive structure comprises an even number of the first conductive sub-layers; and the orthographic projections of at least two of the first conductive sub-layers on the dielectric substrate at least partially overlap, and the flow directions of the currents of both are the same.

6. The inductance structure according to claim 5, wherein the orthographic projection of at least one of the first conductive sub-layers on the dielectric substrate and the orthographic projection of the second conductive sub-layer on the dielectric substrate at least partially overlap, and the flow directions of the currents of both are the same.

7. The inductance structure according to claim 2, wherein when the first conductive structure comprises the at least three first conductive sub-layers and the second conductive structure comprises one of the second conductive sub-layers,
the first conductive structure comprises an odd number of the first conductive sub-layers; and the orthographic projections of at least two of the first conductive sub-layers on the dielectric substrate at least partially overlap, and the flow directions of the currents of both are opposite.

8. The inductance structure according to claim 7, wherein the orthographic projection of at least one of the first conductive sub-layers on the dielectric substrate and the orthographic projection of the second conductive sub-layer on the dielectric substrate at least partially overlap, and the flow directions of the currents of both are opposite.

9. The inductance structure according to claim 5, wherein the first conductive structure comprises a first one of the first conductive sub-layers, a second one of the first conductive sub-layers, a third one of the first conductive sub-layers and a fourth one of the first conductive sub-layers disposed in sequence in a direction away from the dielectric substrate;
wherein the first one of the first conductive sub-layers comprises a plurality of first wirings extending in a first direction and disposed in a second direction, the fourth one of the first conductive sub-layers comprises a plurality of second wirings extending in the first direction and disposed in the second direction, the first direction and the second direction intersect, and the orthographic projections of the first wirings and the second wirings on the dielectric substrate at least partially overlap; and
the second one of the first conductive sub-layers comprises a third wiring, the third one of the first conductive sub-layers comprises a plurality of fourth wirings extending in a third direction and disposed in a fourth direction, the second conductive sub-layer comprises a plurality of fifth wirings extending in the third direction and disposed in the fourth direction, the third direction and the fourth direction intersect, the orthographic projections of the fourth wirings and the fifth wirings on the dielectric substrate at least partially overlap, and the first direction and the third direction intersect.

10. The inductance structure according to claim 9, wherein the inductance structure comprises N first wirings disposed in the same row and N second wirings disposed in the same row, wherein N is a positive integer, and N is greater than or equal to 1; the orthographic projections of an N^{th} one of the first wirings and an N^{th} one of the second wirings on the dielectric substrate overlap, and the flow directions of the currents of both are the same; and
every two of the connection electrodes are divided into one group as a connection electrode group, and the same connection electrode group is in contact with and connected to the same fifth wiring; the same connection electrode group comprises a first connection electrode and a second connection electrode, wherein a region where the first connection electrode is located overlaps with an orthographic projection of a first end of the fourth wiring on the dielectric substrate, and a region where the second connection electrode is located overlaps with an orthographic projection of a second end of the fourth wiring on the dielectric substrate; and the flow directions of the currents of the first connection electrode and the second connection electrode in the same connection electrode group are opposite.

11. The inductance structure according to claim 10, wherein the inductance structure further comprises N fourth wirings disposed in the same row and N+1 fifth wirings disposed in the same row; and the orthographie projections of an N^{th} one of the fourth wirings and an (N+1)^{th} one of the fifth wirings on the dielectric substrate overlap, and the flow directions of the currents of both are the same.

12. The inductance structure according to claim 11, wherein, on the first surface, a second end of a first one of the first wirings and a second end of a first one of the second wirings are respectively electrically connected to a first end of a first one of the fourth wirings; a first end of a second one of the first wirings and a first end of a second one of the second wirings are respectively electrically connected to a second end of a first one of the fourth wirings; and
the second end of the N^{th} one of the first wirings and the second end of the N^{th} one of second wirings are respectively electrically connected to the first end of the N^{th} one of the fourth wirings; and the first end of the (N+1)^{th} one of the first wirings and the first end of the (N+1)^{th} one of the second wirings are respectively electrically connected to the second end of the N^{th} one of the fourth wirings.

13. The inductance structure according to claim 12, wherein the inductance structure comprises N+1 connection electrode groups disposed in the same row; a first end of the third wiring is electrically connected to an (N+1)^{th} one of the second connection electrodes; and a second end of the third wiring is respectively electrically connected to a first end of the first one of the first wirings and a first end of the first one of the second wirings; and
the first end of the first one of the first wirings and the first end of the first one of the second wirings are electrically connected to a first one of the second connection electrodes, respectively; the first end of the first one of the first wirings and the first end of the first one of the second wirings are electrically connected to a second one of the first connection electrodes, respectively; a first end of the N^{th} one of the first wirings and a first end of the N^{th} one of the second wirings are electrically connected to an N^{th} one of the second connection electrodes, respectively; and the second end of the N^{th} one of the first wirings and the second end of the N^{th} one of the second wirings are electrically connected to an (N+1)^{th} one of the first connection electrodes, respectively.

14. The inductance structure according to claim 13, wherein the orthographic projection of the third wiring except the regions of the first end and the second end thereof on the dielectric substrate does not overlap with a region where the connection electrode group is located.

15. The inductance structure according to claim 10, wherein the inductance structure further comprises N+1 fourth wirings disposed in the same row and N+1 fifth wirings disposed in the same row; and
the orthographic projections of an N^{th} one of the fourth wiring and an N^{th} one of the fifth wiring on the dielectric substrate overlap, and the flow directions of the currents of both are the same.

16. The inductance structure according to claim 15, wherein, on the first surface, a second end of a first one of the fourth wirings is electrically connected to a first end of a first one of the first wirings and a first end of a first one of the second wirings, respectively; a first end of an (N+1)^{th} one of the fourth wirings is electrically connected to a second end of a N^{th} one of the first wirings and a second end of an N^{th} one of the second wirings, respectively; and a second end of the (N+1)^{th} one of the fourth wirings is electrically connected to a first end of an (N+1)^{th} one of the first wirings and a first end of an (N+1)^{th} one of the second wirings, respectively.

17. The inductance structure according to claim 16, wherein the inductance structure comprises N+1 connection electrode groups disposed in the same row, a first end of the third wiring is electrically connected to an (N+1)^{th} one of the second connection electrode, and a second end of the third wiring is electrically connected to a first end of the first one of the fourth wirings.

18. (canceled)

19. The inductance structure according to claim 7, wherein the first conductive structure comprises a first one of the first conductive sub-layers, a third one of the first conductive sub-layers and a fourth one of the first conductive sub-layers disposed in sequence in a direction away from the dielectric substrate;
the first one of the first conductive sub-layers comprises a plurality of first wirings extending in a first direction and disposed in a second direction, the fourth one of the first conductive sub-layers comprises a plurality of second wirings extending in the first direction and disposed in the second direction, the first direction and the second direction intersect, and the orthographic projections of the first wirings and the second wirings on the dielectric substrate at least partially overlap; and
the third one of the first conductive sub-layers comprises a plurality of fourth wirings extending in a third direction and disposed in a fourth direction, the second conductive sub-layer comprises a plurality of fifth wirings extending in the third direction and disposed in the fourth direction, the third direction and the fourth direction intersect, the orthographic projections of the fourth wirings and the fifth wirings on the dielectric substrate at least partially overlap, and the first direction and the third direction intersect.

20. The inductance structure according to claim 19, wherein the inductance structure comprises N first wirings disposed in the same row, N second wirings disposed in the same row, N+1 fourth wirings disposed in the same row, and N+1 fifth wirings disposed in the same row; wherein N is a positive integer, and N is greater than or equal to 1;
orthographic projections of an N^{th} one of the first wirings and an N^{th} one of the second wirings on the dielectric substrate overlap, and the flow directions of the currents of both are opposite; orthographic projections of an N^{th} one of the fourth wirings and an N^{th} one of the fifth wirings on the dielectric substrate overlap, and the flow directions of the currents of both are opposite; and
every two of the connection electrodes are divided into one group as a connection electrode group, and the same connection electrode group is in contact with and connected to the same fifth wiring; the same connection electrode group comprises a first connection electrode and a second connection electrode, wherein a region where the first connection electrode is located overlaps with orthographic projections of first ends of the fourth wirings on the dielectric substrate, and a region where the second connection electrode is located overlaps with orthographic projections of second ends of the fourth wirings on the dielectric substrate; and the flow directions of the currents of the first connection electrode and the second connection electrode in the same connection electrode group are opposite.

21. (canceled)

22. (canceled)

23. (canceled)

24. (canceled)

25. (canceled)

26. (canceled)

27. (canceled)

28. (canceled)

29. (canceled)

30. A filter, comprising at least one inductance structure according to claim 1 and at least one capacitor.
